(19) United States
(12) Patent Application Publication
(10) Pub. No.: US 2026/0371529 A1
(43) Pub. Date: Nov. 19, 2026

(54) BEARING SYSTEM FOR A COMPRESSOR OF A DATA CENTER COOLING SYSTEM

(71) Applicant: Tyco Fire & Security GmbH, Neuhausen am Rheinfall (CH)

(72) Inventor: Bryson Lee Sheaffer, Mechanicsburg, PA (US)

(21) Appl. No.: 19/678,079

(22) Filed: May 14, 2026

Related U.S. Application Data
(60) Provisional application No. 63/807,433, filed on May 16, 2025.

(51) Int. Cl. H05K 7/20; F16C 19/06; F16C 32/04

(52) U.S. Cl. CPC H05K 7/20354; F16C 19/06; F16C 32/0474; H05K 7/20827; F16C 2360/00

(57) ABSTRACT

A compressor for a data center cooling system includes a compressor housing, a shaft configured to rotate within the compressor housing, and a bearing system. The bearing system includes one or more primary bearings annularly disposed about the shaft, where the one or more primary bearings are configured to control a position of the shaft. The bearing system also includes one or more backup bearings annularly disposed about the shaft, where each backup bearing of the one or more backup bearings includes a contacting surface configured to engage with the shaft during an operational interruption to the one or more primary bearings, and the contacting surface is formed from a non-conductive material.

### CROSS-REFERENCE TO RELATED APPLICATIONS

This application claims priority to and the benefit of U.S. Provisional Patent Application No. 63/807,433, entitled “BEARING SYSTEM FOR A COMPRESSOR OF A COMPUTER COOLING SYSTEM,” filed on May 16, 2025, which is hereby incorporated by reference in its entirety for all purposes.

### BACKGROUND

This section is intended to introduce the reader to various aspects of art that may be related to various aspects of the present disclosure, which are described below. This discussion is believed to be helpful in providing the reader with background information to facilitate a better understanding of the various aspects of the present disclosure. Accordingly, it should be understood that these statements are to be read in this light, and not as admissions of prior art.

Heating, ventilation, air conditioning, and refrigeration (HVAC&R) systems, such as chiller systems (e.g., vapor compression systems), utilize a working fluid (e.g., a refrigerant) that changes phases between vapor, liquid, and combinations thereof in response to exposure to different temperatures and pressures within components of the chiller system. HVAC&R systems may include a compressor for circulating a working fluid (e.g., refrigerant) along a working fluid circuit and through heat exchangers of the HVAC&R system. For example, the HVAC&R system may include a first heat exchanger configured to receive the working fluid and a conditioning fluid to place the working fluid in the heat exchange relationship with the conditioning fluid. The conditioning fluid may be directed from the first heat exchanger to other equipment, such as air handlers, to condition other fluids, such as air or water. The HVAC&R system may also include a second heat exchanger configured to receive the working fluid and a cooling fluid to place the working fluid in the heat exchange relationship with the cooling fluid. In some embodiments, the cooling fluid may be water. Alternatively, the cooling fluid may be another fluid, such as air. Unfortunately, many HVAC&R system configurations are susceptible to various drawbacks, such as limited heat transfer efficiency, incompatibility with certain heating or cooling loads, and so forth.

Further to the points above, data centers typically include racks of servers or other data center equipment that generate a substantial amount of heat during operation. Some data center cooling systems use fans to circulate cooled air through the server racks and provide cooling to the heat-generating equipment. Other data center cooling systems circulate a liquid coolant to the racks to draw heat directly from the heat-generating equipment or use a combination of air and liquid cooling. As data centers expand to support the rapid growth of cloud computing, artificial intelligence, and other modern applications having high computing loads and power densities, data centers demand effective, energy-efficient cooling solutions that serve these applications while mitigating environmental impact.

### SUMMARY

A summary of certain embodiments disclosed herein is set forth below. It should be understood that these aspects are presented merely to provide the reader with a brief summary of these certain embodiments and that these aspects are not intended to limit the scope of this disclosure. Indeed, this disclosure may encompass a variety of aspects that may not be set forth below.

In an embodiment, a compressor for a data center cooling system includes a compressor housing, a shaft configured to rotate within the compressor housing, and a bearing system. The bearing system includes one or more primary bearings annularly disposed about the shaft, where the one or more primary bearings are configured to control a position of the shaft, and one or more backup bearings annularly disposed about the shaft, where each backup bearing of the one or more backup bearings includes a contacting surface configured to engage with the shaft during an operational interruption to the one or more primary bearings, and the contacting surface is formed from a non-conductive material.

In another embodiment, a data center cooling system includes a working fluid circuit configured to direct a working fluid toward electronic equipment disposed along the working fluid circuit to cool the electronic equipment. The data center cooling system also includes a compressor. The compressor includes a compressor housing, a shaft configured to rotate within the compressor housing, a first bearing disposed about the shaft, and a second bearing disposed about the shaft. The first bearing is configured to impart a magnetic force to the shaft to support the shaft, and the second bearing includes a non-conductive material configured to contact the outer surface of the shaft.

In another embodiment, a bearing system for supporting a shaft of a compressor includes a primary bearing disposed about an axis of rotation of the shaft and a backup bearing disposed about the axis of rotation of the shaft. The primary bearing is configured to establish a first clearance distance between the shaft and the primary bearing during operation of the compressor and the primary bearing. The backup bearing is configured to encircle the shaft at a second clearance distance between the backup bearing and the shaft during operation of the compressor and the primary bearing. The second clearance distance is less than the first clearance distance, and an inner surface of the backup bearing includes a non-conductive material configured to contact an outer surface of the shaft during an operational interruption of the primary bearing.

Various refinements of the features noted above may exist in relation to various aspects of the present disclosure. Further features may also be incorporated in these various aspects as well. These refinements and additional features may exist individually or in any combination. For instance, various features discussed below in relation to one or more of the illustrated embodiments may be incorporated into any of the above-described aspects of the present disclosure alone or in any combination. The brief summary presented above is intended only to familiarize the reader with certain aspects and context of embodiments of the present disclosure without limitation to the claimed subject matter.

Various embodiments relate to an HVAC&R system for cooling electronic equipment (e.g., a cooling system for a data center, etc.) where a fluid circuit (e.g., working fluid circuit) extends between a compressor, a condenser, and a heat exchanger coupled to the electronic equipment.

In any of the embodiments disclosed herein:

The condenser may be an air-cooled condenser. The condenser may be remotely located from the compressor. The condenser may be a dry cooler.

The compressor may be an oil-less compressor.

The heat exchanger may be configured to provide single phase or two-phase heat exchange with respect to a working fluid, such as a refrigerant, as it passes through the heat exchanger. The heat exchanger may be a plate heat exchanger coupled to a surface of a computer chip. In some embodiments, the heat exchanger may be a cold plate. In some embodiments, the heat exchanger may be configured to immerse the computer chip within the working fluid.

The compressor may include a bearing system having one or more primary bearings annularly disposed about a shaft of the compressor and one or more backup bearings annularly disposed about the shaft.

The one or more primary bearings may include at least one magnetic bearing. The magnetic bearing may be configured to impart a magnetic force to the shaft to support the shaft, such as in a radial direction or an axial direction. The one or more backup bearings may include at least one mechanical bearing. The mechanical bearing may include a ball bearing, a roller bearing, or both.

The one or more backup bearings may be configured to support the shaft of the compressor during an operational interruption to the one or more primary bearings, during non-operation of the compressor, or both.

The one or more primary bearings may be configured to establish a first clearance distance between the one or more primary bearings and the shaft during operation of the one or more primary bearings. The one or more backup bearings may be disposed around the shaft at a second clearance distance between the one or more backup bearings and the shaft. The first clearance distance may be greater than the second clearance distance.

The compressor may include a first bearing assembly having a first primary bearing and a first backup bearing. The compressor may further include a second bearing assembly having a second primary bearing and a second backup bearing. The first bearing assembly may be disposed about a first end of the shaft. The second bearing assembly may be disposed about a second end of the shaft. The second end may be opposite the first end. The first backup bearing may be positioned outboard of the first primary bearing relative to a longitudinal center of the shaft.

At least one of the backup bearings may include a contacting surface configured to engage with the shaft during an operational interruption to the one or more primary bearings. The non-conductive material may include a ceramic, silicon nitride, zirconium dioxide, or any combination thereof. In some embodiments, at least a portion of at least one of the primary bearings may include an additional non-conductive material. The additional non-conductive material may be different than the non-conductive material of the backup bearing.

The compressor may include a bearing housing configured to support and retain at least one primary bearing, at least one backup bearing, or any combination thereof.

### BRIEF DESCRIPTION OF THE DRAWINGS

Various aspects of this disclosure may be better understood upon reading the following detailed description and upon reference to the drawings in which:

FIG. 1 is a perspective view of an embodiment of a data center room including racks served by a data center cooling system, in accordance with an aspect of the present disclosure;

FIG. 2 is a block diagram of an embodiment of a data center cooling system, such as the data center cooling system of FIG. 1, in accordance with an aspect of the present disclosure;

FIG. 3 is a block diagram of an embodiment of a rack of a data center room, such as the data center room of FIG. 1, in greater detail, in accordance with an aspect of the present disclosure;

FIG. 4 is a perspective view of an embodiment of a server tray which can be installed in the racks of a data center room, such as the data center room of FIG. 1, in accordance with an aspect of the present disclosure;

FIG. 5 is a block diagram of an embodiment of a liquid cooling circuit which can be used in a data center cooling system, such as the data center cooling system of FIG. 1, in accordance with an aspect of the present disclosure;

FIG. 6 is a block diagram of an embodiment of an air-cooling circuit which can be used in a data center cooling system, such as the data center cooling system of FIG. 1, in accordance with an aspect of the present disclosure;

FIG. 7 is a schematic of an embodiment of an HVAC&R system including a chiller system configured to provide cooling to electronic equipment, in accordance with an aspect of the present disclosure;

FIG. 8 is a schematic of an embodiment of an HVAC&R system, such as a data center cooling system, including a chiller system configured to provide cooling to electronic equipment, in accordance with an aspect of the present disclosure;

FIG. 9 is a cross-sectional view of an embodiment of piping of a computer cooling system configured to direct a working fluid to electronic equipment, in accordance with an aspect of the present disclosure;

FIG. 10 is a cross-sectional side view of an embodiment of a compressor of a chiller system, illustrating a bearing system of the compressor, in accordance with an aspect of the present disclosure;

FIG. 11 is a cross-sectional side view of an embodiment of a portion of a compressor of a chiller system, illustrating a bearing assembly disposed about a shaft of the compressor, in accordance with an aspect of the present disclosure; and

FIG. 12 is an axial view of an embodiment of a bearing assembly of a compressor, in accordance with an aspect of the present disclosure.

### DETAILED DESCRIPTION

One or more specific embodiments will be described below. In an effort to provide a concise description of these embodiments, not all features of an actual implementation are described in the specification. It should be appreciated that in the development of any such actual implementation, as in any engineering or design project, numerous implementation-specific decisions must be made to achieve the developers’ specific goals, such as compliance with system-related and business-related constraints, which may vary from one implementation to another. Moreover, it should be appreciated that such a development effort might be complex and time consuming, but would nevertheless be a routine undertaking of design, fabrication, and manufacture for those of ordinary skill having the benefit of this disclosure.

When introducing elements of various embodiments of the present disclosure, the articles “a,” “an,” and “the” are intended to mean that there are one or more of the elements. The terms “comprising,” “including,” and “having” are intended to be inclusive and mean that there may be additional elements other than the listed elements. Additionally, it should be understood that references to “one embodiment” or “an embodiment” of the present disclosure are not intended to be interpreted as excluding the existence of additional embodiments that also incorporate the recited features.

As used herein, the terms “approximately,” “generally,” “substantially,” and so forth, are intended to convey that the property value being described may be within a relatively small range of the property value, as those of ordinary skill would understand. For example, when a property value is described as being “approximately” equal to (or, for example, “substantially similar” to) a given value, this is intended to convey that the property value may be within +/- 5%, within +/- 4%, within +/- 3%, within +/- 2%, within +/- 1%, or even closer, of the given value. Similarly, when a given feature is described as being “substantially parallel” to another feature, “generally perpendicular” to another feature, and so forth, this is intended to convey that the given feature is within +/- 5%, within +/- 4%, within +/- 3%, within +/- 2%, within +/- 1%, or even closer, to having the described nature, such as being parallel to another feature, being perpendicular to another feature, and so forth. Mathematical terms, such as “parallel” and “perpendicular,” should not be rigidly interpreted in a strict mathematical sense, but should instead be interpreted as one of ordinary skill in the art would interpret such terms. For example, one of ordinary skill in the art would understand that two lines that are substantially parallel to each other are parallel to a substantial degree but may have minor deviation from exactly parallel.

As used herein, an HVAC&R system (e.g., data center cooling system) may include any number of components configured to enable regulation of one or more parameters related to climate characteristics, such as temperature, humidity, air flow, pressure, air quality, and so forth. For example, an “HVAC&R system” as used herein may be defined as a system configured to perform operations including one or more of heating, cooling, ventilation, dehumidification, pressurization, refrigeration, filtration, or any combination thereof. Indeed, certain HVAC&R systems incorporating the present techniques may be configured to perform certain operations (e.g., cooling) but not others (e.g., heating). Components or parts of an “HVAC&R system” may include, but are not limited to, all, some of, or individual parts such as a heat exchanger, a fluid flow control device, such as a valve, a sensor configured to detect a climate characteristic or operating parameter, a filter, a control device configured to regulate operation of an HVAC&R system component, a component configured to enable regulation of one or more climate characteristics, or a combination thereof. The embodiments described herein may be utilized in a variety of applications to control climate characteristics, such as residential, commercial, industrial, transportation, or other applications where climate control is desired.

A heating, ventilation, air conditioning, and/or refrigeration (HVAC&R) system (e.g., chiller system, air-cooled chiller system) may be implemented to thermally regulate space and/or components within a building, home, data center, or other suitable structure. HVAC&R systems may also be utilized to thermally regulate systems and/or components that demand thermal conditioning (e.g., provide cooling/heat rejection to components within a facility such as a data center). In general, HVAC&R systems include a vapor compression system (e.g., vapor compression circuit) that transfers thermal energy between a working fluid (e.g., refrigerant) and a fluid to be conditioned, such as water, air, or another suitable fluid. The vapor compression system may include one or more heat exchangers, such as a condenser and an evaporator, that are fluidly coupled to one another via a working fluid circuit (e.g., refrigerant circuit, one or more conduits). The vapor compression system may also include a compressor configured to circulate the working fluid through the working fluid circuit and thereby enable the transfer of thermal energy between the condenser and the evaporator and respective fluids directed through the condenser and the evaporator.

In some applications, the HVAC&R system may be or include a chiller system configured to condition a conditioning fluid (e.g., water) that is directed to downstream equipment, such as air handlers, computer equipment, heat exchangers, and/or other components configured to utilize the conditioning fluid to cool a conditioned space, another device or component (e.g., computer system, computer server, electronic equipment), or both. To this end, the chiller system may include an evaporator configured to transfer heat from the conditioning fluid to a working fluid circulated through the chiller system. The chiller system may also include a condenser configured to transfer heat from the working fluid to a cooling fluid. In some applications, the cooling fluid may be water (e.g., water-cooled chiller). Alternatively, the cooling fluid may be air (e.g., air-cooled chiller). In yet further implementations, combinations of air and water may be used as the cooling fluid for the chiller system.

In some implementations, HVAC&R systems, such as chiller systems, dry coolers, and/or cooling towers, are utilized to cool electronic equipment. For example, electronic equipment, such as computers, servers, storage devices, network equipment, power supplies, computing systems, and/or information technology (IT) hardware or infrastructure, may generate substantial amounts of heat during operation. In order to facilitate proper operation of such electronic equipment, the generated heat should be transferred and/or rejected to another suitable location or environment in order to maintain operating temperatures of the electronic equipment below relevant threshold temperatures. It will be appreciated that some facilities, such as data centers, may house considerable amounts of electronic equipment that generate heat in a relatively small area. Accordingly, chiller systems may be implemented, along with other cooling system components, to enable rejection of heat generated by such electronic equipment.

In some implementations, the chiller systems may operate to cool a fluid that is placed in a heat exchange relationship with the electronic equipment. For example, some cooling systems may include coolant distribution units (CDUs) that include a heat exchanger configured to transfer heat between a conditioning fluid generated (e.g., cooled) by the chiller system and a coolant that is placed in a heat exchange relationship with the electronic equipment. The conditioning fluid cooled by the chiller system may be a flow of water (e.g., facility water) supplied or provided by a facility housing the electronic equipment (e.g., data center), and the coolant may be another flow of water (e.g., technical water, IT water) suitable for placing in a heat exchange relationship with the electronic equipment. The flow of water cooled by the chiller system may not be suitable for placing in a heat exchange relationship with the electronic equipment. Therefore, the heat exchanger of the CDU may isolate the conditioning fluid from the electronic equipment. Unfortunately, the efficiency of such systems may be limited due to the use of multiple stages of heat transfer between the chiller system and the electronic equipment.

Additionally, or alternatively, some cooling systems may include a chiller system having a working fluid circuit configured to circulate a working fluid (e.g., refrigerant) to cool a conditioning fluid (e.g., water, glycol, water and glycol mixture), and a conditioning fluid circuit configured to circulate the conditioning fluid between the chiller system and the electronic equipment. More specifically, the conditioning fluid circuit is configured to place the conditioning fluid in a heat exchange relationship with the working fluid circulated through the working fluid circuit of the chiller system and is also configured to place the conditioning fluid in a heat exchange relationship with the electronic equipment. Such systems may not include a CDU with a heat exchanger configured to transfer heat between the conditioning fluid and a coolant directed to the electronic equipment. Thus, a stage of heat transfer between the chiller system and the electronic equipment frequently included in other cooling systems may be omitted, which enables improved efficiency of the cooling system.

In other embodiments, the chiller system may be configured to cool the working fluid and direct the working fluid to the electronic equipment to place the working fluid in a heat exchange relationship with the electronic equipment, such as via a cold plate, a tube, a flow path, a channel, a vessel, and/or immersion cooling techniques. In such embodiments, the cooling system may or may not include a conditioning fluid circuit configured to place a conditioning fluid in a heat exchange relationship with the electronic equipment. Thus, another stage of heat transfer between the chiller system and the electronic equipment frequently included in other cooling systems may be omitted, which enables even further improved efficiency of the cooling system.

In certain cases, it may be desirable to mitigate exposure of a fluid (e.g., working fluid, conditioning fluid) directed toward the electronic equipment to potential particulates or contaminants (e.g., in embodiments in which a working fluid is routed directly to the electronic equipment without a separate conditioning fluid circuit). For example, exposure of the fluid (e.g., working fluid, conditioning fluid) to certain materials, such as materials that may be susceptible to corrosion and/or degradation (e.g., mechanical, physical, chemical, and/or electrochemical corrosion), may cause particulates, contaminants, or other impurities to mix with (e.g., become entrained within) the fluid before the fluid is delivered to the electronic equipment. Additionally, or alternatively, operation of certain componentry of a cooling system may generate impurities to which the fluid may be inadvertently exposed.

For example, during operation of a compressor of an HVAC&R system incorporated with a cooling system, a shaft of the compressor may rotate and, in some instances, may contact and/or engage with other components (e.g., bearings) of the compressor. In some systems, such contact may include metal-to-metal contact (e.g., metal to metal skidding, contact between a metallic shaft and a metallic bearing). The metal-to-metal contact may generate impurities and/or contaminants (e.g., particulates) that may be entrained within the working fluid directed through the compressor. Entrainment of impurities and/or contaminants within the working fluid may cause exposure of downstream components along the working fluid circuit (e.g., electronic equipment) to the impurities and/or contaminants as the working fluid is delivered to the downstream components. Unfortunately, introduction of a fluid having particulates, contaminants, or other impurities mixed therein may cause wear and/or degradation to the electronic equipment, and in some cases, may cause operational disruptions of the electronic equipment. Thus, it is now recognized that improved systems and methods for mitigating potential exposure of a fluid (e.g., working fluid, conditioning fluid) directed to electronic equipment to contaminants, particulates, and/or other impurities that may otherwise affect operation of the electronic equipment are desired.

Accordingly, present embodiments include systems and methods for mitigating the generation or creation of particulates, contaminants, and/or impurities (e.g., mitigating or reducing metal-to-metal contact in a compressor of a cooling system) and/or mitigating the exposure of a fluid (e.g., working fluid or conditioning fluid that may be directed toward electronic equipment to cool the electronic equipment) to particulates, contaminants, or other impurities (e.g., materials susceptible to chemical or electrochemical corrosion). For example, present embodiments may include a compressor configured to pressurize and circulate a working fluid through a working fluid circuit of a cooling system (e.g., chiller system). The compressor may include one or more components that form a portion of the working fluid circuit and are configured to enable pressurization of the working fluid while mitigating exposure of the working fluid to potential particulates or contaminants within the compressor. In certain embodiments, the compressor may be arranged or configured in a manner that reduces an amount of metal-to-metal contact within the compressor during operation of the compressor, thereby reducing an amount of particulates, contaminants, and impurities that may be entrained into the working fluid directed through the compressor and, in some configurations, subsequently directed to electronic equipment to cool the electronic equipment. For example, the compressor may include a bearing system having one or more bearing assemblies configured to support and facilitate rotation of a shaft of the compressor relative to a housing of the compressor.

In accordance with present techniques, the bearing system may include one or more primary bearings (e.g., primary bearing system, primary bearing assemblies, magnetic bearings) and one or more backup bearings. In certain embodiments, the primary bearings may be magnetic bearings configured to impart magnetic forces onto the shaft and/or other components of the shaft to enable desired positioning and/or support of the shaft (e.g., and components connected thereto, such as an impeller of the compressor) during operation of the compressor. For example, the magnetic forces imparted onto the shaft may cause the shaft to levitate during operation without physical contact between the shaft and the magnetic bearings. Thus, during operation, the magnetic bearings may be configured to limit an amount of metal-to-metal contact (e.g., metal-to-metal skidding) within the compressor. The one or more backup bearings may be configured to support the shaft of the compressor and enable rotation of the shaft in an event that operation (e.g., normal operation) of the primary bearings is inadvertently interrupted. The backup bearings may temporarily enable continued operation and/or controlled (e.g., regulated) slowdown of the compressor (e.g., rotation of the shaft) during operational interruption of the primary bearings.

In certain embodiments, the backup bearings may be mechanical bearings (e.g., ball bearings, roller bearings, angular contact ball bearings, deep groove ball bearings). For example, the backup bearings may have raceways (e.g., races, inner raceway, inner race, outer raceway, outer race) and a number of balls or rollers (e.g., bearing elements) positioned between the raceways, thereby enabling relative movement between an inner raceway and an outer raceway of the backup bearing. At least a portion of the backup bearings (e.g., the inner raceway) that is configured to directly contact the shaft of the compressor (e.g., during operational interruption of the primary bearings) may be formed from any suitable non-conductive (e.g., non-metallic) material (e.g., ceramic, silicon nitride, zirconium dioxide). By utilizing a non-conductive material to form at least a portion of the backup bearings that directly contacts the shaft of the compressor, metal-to-metal contact within the compressor may be reduced and/or avoided, thereby reducing potential creation of particulates, contaminants, or impurities within the compressor that may otherwise be created via metal-to-metal contact. In this way, the working fluid directed through the compressor may remain free or substantially free of particulates, contaminants, or other impurities, such that the working fluid may be suitable for placing in a heat transfer arrangement with electronic equipment.

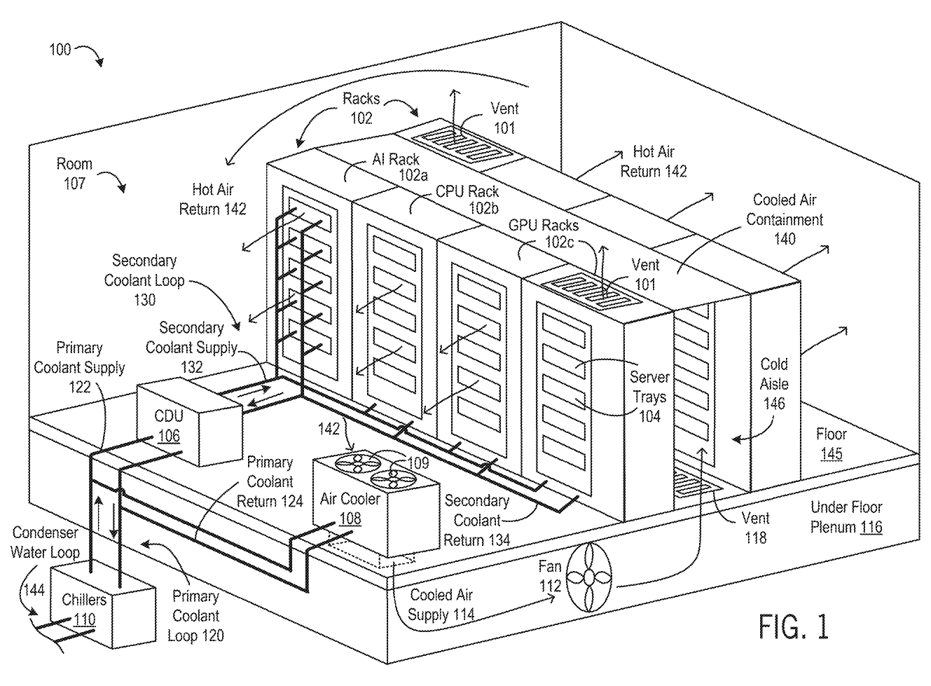

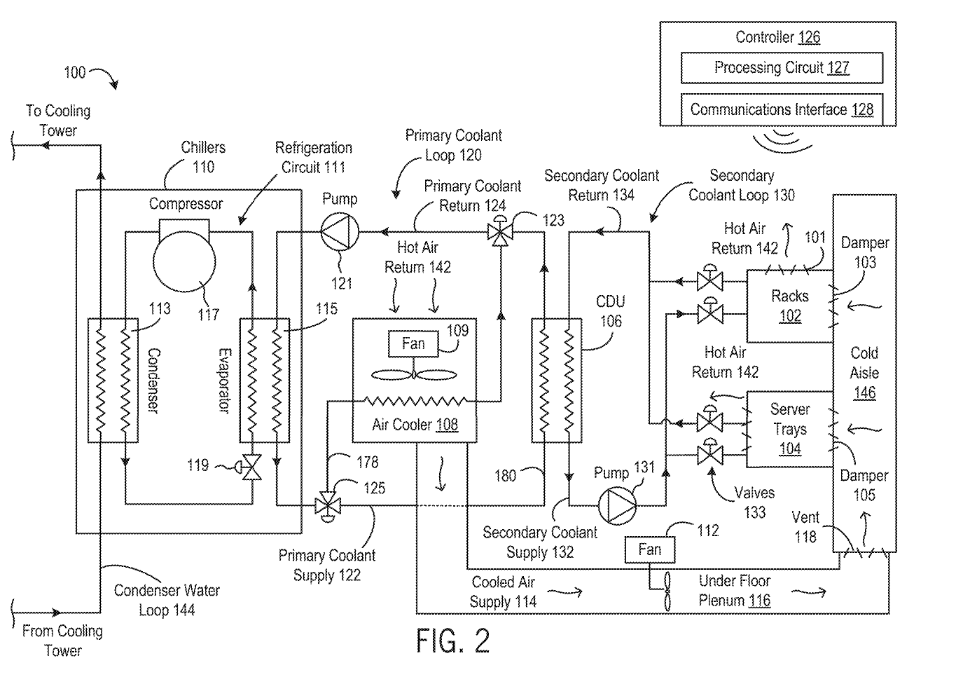

Referring now to FIGS. 1 and 2, a data center cooling system 100 (e.g., computer cooling system) is shown, according to an exemplary embodiment. FIG. 1 is a perspective view of a data center room 107 served by data center cooling system 100, whereas FIG. 2 is a block diagram of data center cooling system 100. Data center room 107 is shown to include several racks 102 (e.g., cabinets), such as racks 102a, 102b, and 102c (e.g., collectively racks 102) containing server trays 104 (e.g., server blades, server boxes, computer enclosures, other computing devices, etc.). Racks 102 may be arranged in rows (e.g., side-to-side) to form aisles between adjacent rows of racks 102. In some embodiments, the aisles form an alternating sequence of cold aisles and hot aisles on opposite sides of racks 102. For example, the space between the two rows of racks 102 in FIG. 1 is shown as a cold aisle 146 which provides a cooled air supply 114 to racks 102. Cold aisle 146 may be bounded on opposite sides by racks 102, on the bottom by floor 145 (i.e., the floor of data center room 107), and on the top by a cooled air containment 140 (e.g., a solid surface) to contain cooled air supply 114 within cold aisle 146. In some embodiments, cooled air containment 140 also extends vertically along the ends of cold aisle 146 to form a wall perpendicular to both the top surface of cooled air containment 140 and the front and rear surfaces of racks 102 (i.e., the surfaces on which server trays 104 are visible) to prevent cooled air supply 114 from escaping cold aisle 146 via the ends.

In some embodiments, the adjacent rows of racks 102 are arranged front-to-front (i.e., such that the front surfaces of adjacent rows of racks 102 face each other) and back-to-back (i.e., such that the rear surfaces of adjacent rows of racks 102 face each other). For example, as shown in FIG. 1, cold aisle 146 is located between the rear surfaces of adjacent rows of racks 102, whereas the front surfaces of racks 102 face toward hot aisles. In some embodiments, a vent 118 is located along floor 145 of cold aisle 146 to allow cooled air supply 114 to flow into cold aisle 146 from an under floor plenum 116. Racks 102 may draw or receive cooled air supply 114 into racks 102 from cold aisle 146 and pass cooled air supply 114 over heat-producing data center equipment contained within racks 102 (e.g., CPUs, GPUs, dual inline memory modules (DIMMs), servers, power supplies, etc.) which transfer heat to cooled air supply 114. The heated airflow then exits racks 102 through the front surfaces of racks 102 (i.e., the surfaces opposite cold aisle 146) and/or through the top surfaces of racks 102 via vents 101. The heated airflow exiting racks 102 then flows into data center room 107 as a hot air return 142.

In some embodiments, racks 102 can be designated as a particular type based on the type of computing devices they contain (e.g., CPUs, GPUs, DIMMs, ASICs, etc.) and/or based on the type of computing application they run during operation (e.g. AI applications, high performance computing applications, standard computing applications, etc.). For example, rack 102a is shown as an AI rack, rack 102b is shown as a CPU rack, and racks 102c are shown as GPU racks. Similarly, server trays 104 can be designated as AI server trays, CPU server trays, or GPU server trays based on the type of computing devices within server trays 104 and/or the type of computing applications by server trays 104. In some embodiments, data center cooling system 100 uses the type of racks 102 and/or server trays 104 to determine the amount of cooling to provide to each of racks 102 and/or server trays 104. For example, AI rack 102a and GPU racks 102c may require a higher amount of cooling whereas CPU rack 102b may require a lower amount of cooling. Similarly, AI server trays and GPU server trays may require a higher amount of cooling whereas CPU server trays may require a lower amount of cooling.

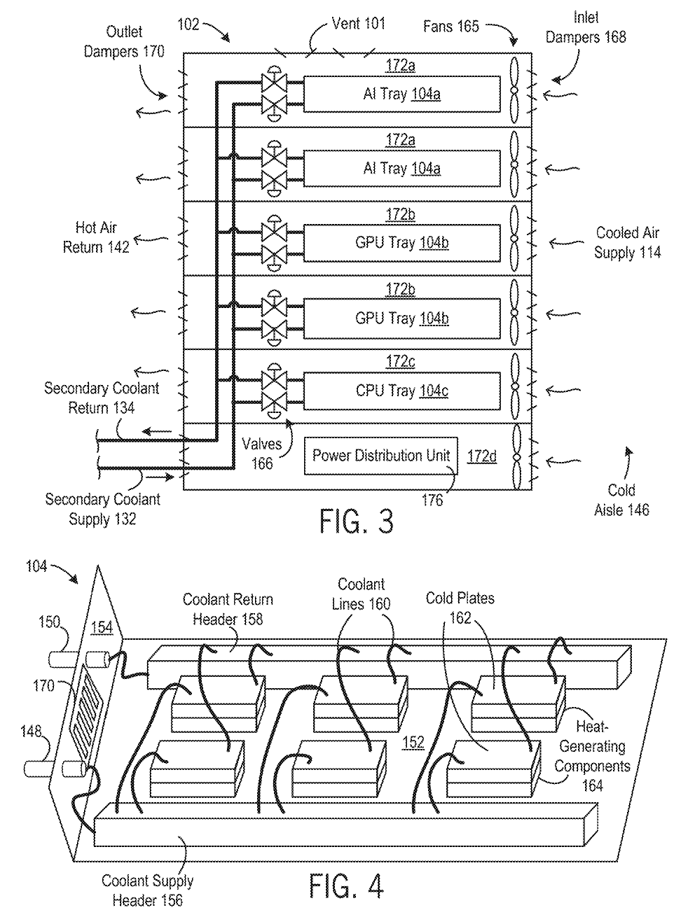

In various embodiments, racks 102 may include top vents 101 located on the top surfaces of racks 102, front vents aligned with each of server trays 104 on the front surfaces of racks 102, or a combination of top vents 101 and front vents. In some embodiments, one or more of racks 102 includes a top vent 101, whereas one or more other racks 102 include front vents. In racks 102 with top vents 101, some or all of the internal volume within such racks 102 may by fluidly connected to allow some or all of the airflow through such racks 102 to exit racks 102 via top vents 101. In racks 102 with front vents aligned with server trays 104, some or all of the internal volume within racks 102 may be portioned into separate compartments within which one or more of server trays 104 are contained. Each compartment may receive a separate airflow stream to provide targeted cooling to the heat-generating equipment contained within the corresponding compartment. One example of how racks 102 can be partitioned into isolated compartments is described in greater detail with reference to FIG. 3. Although only one of GPU racks 102c is shown with top vents 101 in FIG. 1, it is contemplated that any number or type of racks 102 can include top vents 101 and/or or front vents regardless of the type of rack 102. For example, any of AI rack 102a, CPU rack 102b, and/or GPU racks 102c can include front vents and/or top vents 101 in various embodiments.

Still referring to FIGS. 1 and 2, data center cooling system 100 is shown to include air cooling equipment (shown in subsequent figures as air cooling system 230) which provides air cooling to racks 102. The air cooling equipment are shown to include an air cooler 108 and fans 109 and 112 which operate to circulate airflow between air cooler 108 and racks 102. Fan 109 may be positioned to move hot air return 142 from data center room 107 into and through air cooler 108. Air cooler 108 may include any of a variety of airside HVAC equipment configured to provide cooling to hot air return 142 and/or generate cooled air supply 114. For example, air cooler 108 may include one or more computer room air conditioner (CRAC) units, computer room air handler (CRAH) units, direct evaporative cooling (DEC) units, indirect evaporative cooling (IEC) units, free cooling units (e.g., airside economizers), or any other type of airside HVAC equipment. Air cooler 108 may include one or more heat exchangers configured to absorb heat from hot air return 142 to generate cooled air supply 114. In various embodiments, air cooler 108 can be configured to provide mechanical cooling, free cooling, or a combination of mechanical cooling and free cooling to generate cooled air supply 114. For example, air cooler 108 can include any combination of mechanical cooling and free cooling components, as described U.S. Patent No. 9,982,903 granted May 29, 2018, the entire disclosure of which is incorporated by reference herein. Fan 109 can be operated to adjust the airflow rate of cooled air supply 114 and/or the amount of cooling provided to hot air return 142 to generate cooled air supply 114 by controlling the rate at which the airflow passes through air cooler 108.

In some embodiments, air cooler 108 generates cooled air supply 114 by removing heat from hot air return 142. For example, as shown in FIG. 2, air cooler 108 may include an internal heat exchanger (e.g., an air-to-liquid heat exchanger, a cooling coil, etc.) configured to transfer heat from the airflow passing through air cooler 108 into a primary coolant circulating through air cooler 108 via the heat exchanger. In some embodiments, air cooler 108 is configured to generate cooled air supply 114 by exhausting hot air return 142 (e.g., outdoors or into another space other than data center room 107) and drawing cool air into air cooler 108 (e.g., from outdoors or another space) to replace the exhausted hot air return 142. For example, air cooler 108 may operate as an airside economizer configured to provide free cooling to data center room 107 and/or racks 102 when outdoor temperature conditions permit the use of outdoor air. In various embodiments, air cooler 108 may generate cooled air supply 114 by mechanical cooling (e.g., removing heat from hot air return 142), by free cooling (e.g., replacing some or all of hot air return 142 with cooler outdoor air), or by using a combination of mechanical cooling and free cooling.

Air cooler 108 may deliver cooled air supply 114 into under floor plenum 116 which occupies a space below floor 145 of data center room 107. Fan 112 may be located within under floor plenum 116 and configured to move cooled air supply 114 through under floor plenum 116 and into cold aisle 146 via vent 118. Fan 112 can be operated to control the flow rate of cooled air supply 114 through under floor plenum 116 and into cold aisle 146. In some embodiments, data center cooling system 100 may include dampers 103 positioned at the air inlets of racks 102 (e.g., between racks 102 and cold aisle 146 as shown in FIG. 2). Dampers 103 can be operated to modulate the amount of airflow into each of racks 102 individually. Similarly, data center cooling system 100 may include dampers 105 positioned at the air inlets of server trays 104 (e.g., between server trays 104 and cold aisle 146 as shown in FIG. 2). In some embodiments, dampers 103 are used for racks 102 in which some or all of the internal volume is fluidly connected such that the amount of airflow into each rack 102 is controllable at the rack level. Conversely, dampers 105 may be used for racks 102 which are subdivided into compartments to control the airflow through each compartment individually. Although dampers 103 and 105 are shown at the inlets of racks 102 and server trays 104 respectively in FIG. 2, it is contemplated that dampers 103 and dampers 105 may be located at the outlets of racks 102 and server trays 104 or otherwise positioned within racks 102 to control the amount of airflow through each of racks 102 and/or compartments of racks 102.

Still referring to FIGS. 1 and 2, data center cooling system 100 is shown to include liquid cooling equipment (shown in subsequent figures as liquid cooling system 220) which provides liquid cooling to racks 102. The liquid cooling equipment are shown to include a coolant distribution unit (CDU) 106, chillers 110 (e.g., heating, ventilation, air conditioning, and/or refrigeration (HVAC&R) equipment), a primary coolant loop 120, a secondary coolant loop 130, and a condenser water loop 144. Chillers 110 may be configured to provide cooling to a primary coolant (e.g., water, glycol, CO2, ammonia, etc.) which circulates between chillers 110, air cooler 108, and CDU 106 via primary coolant loop 120. As shown in FIG. 2, chillers 110 may include an internal refrigeration circuit 111 (e.g., working fluid circuit, vapor compression circuit) including a compressor 117, a condenser 113, an expansion valve 119, and an evaporator 115. Compressor 117 can be configured to circulate a refrigerant between condenser 113 and evaporator 115 via refrigeration circuit 111. Compressor 117 operates to compress the refrigerant to a high pressure, high temperature state. The compressed refrigerant flows through condenser 113, which transfers heat from the refrigerant in refrigeration circuit 111 to the water in condenser water loop 144. The cooled refrigerant then flows through expansion valve 119, which expands the refrigerant to a low temperature, low pressure state. The expanded refrigerant flows through evaporator 115, which transfers heat from the primary coolant in primary coolant loop 120 to the refrigerant in refrigeration circuit 111. In some embodiments, condenser water loop 144 circulates water or another coolant between condenser 113 and a cooling tower or other location (e.g., another heat exchanger) where the water rejects heat before returning to condenser 113.

In various embodiments, primary coolant loop 120 circulates the primary coolant between chillers 110 and one or both of CDU 106 and air cooler 108. Primary coolant loop 120 may include a pump 121 configured to circulate the primary coolant within primary coolant loop 120. Pump 121 can be operated to control the flow rate of the primary coolant within primary coolant loop 120. In some embodiments, primary coolant loop 120 includes one or more valves 123 and 125 configured to control the flow of the primary coolant through branches 178 and 180 of primary coolant loop 120. Branch 180 may pass through CDU 106, whereas branch 178 may pass through air cooler 108. In some embodiments, as shown in FIG. 2, valves 123 and 125 may be three-way valves positioned at the intersections of branches 178 and 180 (i.e., the location at which primary coolant loop 120 splits into branches 178 and 180) and can be operated to control the flow of the primary coolant supply 122 from chillers 110 to CDU 106 and/or to air cooler 108. Alternatively, valves 123 and 125 can be two-way valves having a single inlet and a single outlet (e.g., on/off valves, adjustable valves, modulating valves, etc.) located along each branch 178 and 180 of primary coolant loop 120 such that valves 123 and 125 can be operated to control the flow of the primary coolant to each of air cooler 108 and CDU 106 individually. In various embodiments, such two-way valves can be located between the intersections shown in FIG. 2 and air cooler 108 (e.g., upstream and/or downstream of air cooler 108), between the intersections shown in FIG. 2 and CDU 106 (e.g., upstream and/or downstream of CDU 106), or otherwise positioned along branches 178 and 180 to selectively control the flow rate of primary coolant supply 122 along each of branches 178 and 180.

The liquid coolant in primary coolant loop 120 is cooled by chillers 110 in evaporator 115 to generate primary coolant supply 122. Although only one evaporator 115 is shown in FIG. 2 for ease of illustration, it is contemplated that primary coolant loop 120 may include one or more evaporators 115 arranged in parallel (e.g., parts of parallel chillers 110) or in series (e.g., parts of series chillers 110) to provide cooling to the liquid coolant circulating in primary coolant loop 120. Primary coolant supply 122 flows through primary coolant loop 120 into branch 178 which passes through air cooler 108 and/or branch 180 which passes through CDU 106. The primary coolant absorbs heat from hot air return 142 in air cooler 108 and/or from the secondary coolant in CDU 106 to generate primary coolant return 124. Primary coolant return 124 then returns from air cooler 108 and/or CDU 106 to chillers 110 to be cooled once again and the cycle repeats.

In various embodiments, the liquid coolant circulating in primary coolant loop 120 can be cooled using any combination of mechanical cooling and/or free cooling. For example, in one embodiment a first portion (e.g., a first branch) of primary coolant loop 120 may pass through chillers 110 to receive mechanical cooling from chillers 110, whereas a second portion (e.g., a second branch) of primary coolant loop 120 may pass through one or more free cooling devices (e.g., outdoor air heat exchangers, cooling towers, etc.) to receive free cooling when outdoor temperature conditions permit using free cooling. Several examples of how a hybrid mechanical cooling and free cooling system can be constructed are described in detail in U.S. Patent No. 9,982,903 incorporated by reference above.

In some embodiments, data center cooling system 100 includes multiple primary coolant loops 120 configured to circulate the primary coolant at different temperatures. For example, a first primary coolant loop 120 may be configured to circulate a relatively higher temperature coolant, a second primary coolant loop 120 may be configured to circulate relatively colder temperature coolant, and a third primary coolant loop 120 may be configured to circulate coolant at a medium temperature between the relatively higher and lower temperatures. The

CDU 106 can be configured to transfer heat between the primary coolant in primary coolant loop 120 and the secondary coolant (e.g., water, glycol, CO2, ammonia, etc.) in secondary coolant loop 130. It is expected that the secondary coolant in secondary coolant loop 130 is warmer than the primary coolant in primary coolant loop 120 and thus the direction of heat transfer within CDU 106 is from the secondary coolant to the primary coolant (i.e., from secondary coolant loop 130 to primary coolant loop 120). In various embodiments, the primary coolant and the secondary coolant may be the same or different coolants and may be kept fluidly separate from each other by containing them within their respective coolant loops 120 and 130. CDU 106 is shown as a heat exchanger (e.g., a liquid-to-liquid heat exchanger, a heat exchange coil, etc.) which receives primary coolant supply 122 from primary coolant loop 120 and secondary coolant return 134 from secondary coolant loop 130. CDU 106 may transfer heat from the relatively warmer secondary coolant return 134 into the relatively colder primary coolant supply 122 to provide cooling to the secondary coolant and generate secondary coolant supply 132.

Secondary coolant loop 130 can be configured to circulate the secondary coolant between CDU 106 and one or both of racks 102 and server trays 104. Secondary coolant loop 130 may include a pump 131 configured to circulate the secondary coolant within secondary coolant loop 130. Pump 131 can be operated to control the flow rate of the secondary coolant within secondary coolant loop 130 and/or the rate of heat transfer between the primary coolant and the secondary coolant in CDU 106. In some embodiments, secondary coolant loop 130 includes one or more valves 133 configured to control the flow of the secondary coolant through racks 102 and/or server trays 104. In various embodiments, valves 133 may be located at the coolant inlets of racks 102 or server trays 104 and/or at the coolant outlets of racks 102 or server trays 104 to control the flow of the secondary coolant through each of racks 102 and/or server trays 104 individually. Although valves 133 are shown at both the inlets and outlets of racks 102 and server trays 104 in FIG. 2, it is contemplated that such an arrangement may be redundant and that a single valve located at either the inlet or the outlet of each of racks 102 or server trays 104 may be sufficient to control the flow of the secondary coolant through each of racks 102 and server trays 104 individually.

In some embodiments, secondary coolant loop 130 provides the secondary coolant to one or more of racks 102 in parallel. For example, as shown in FIG. 1, the three racks 102b and 102c are shown receiving secondary coolant supply 132 from secondary coolant loop 130 and discharging secondary coolant return 134 as an output of racks 102. Such racks 102b and 102c may have internal valves (e.g., valves 166 shown in FIG. 3), pumps, or other flow control devices which can be operated to independently control the flow of secondary coolant supply 132 to each of server trays 104 and/or individual heat-generating components 164 located within racks 102b and 102c, as described in greater detail with reference to FIGS. 3 and 4. In some embodiments, secondary coolant loop 130 provides the secondary coolant directly to one or more of server trays 104 in parallel. For example, as shown in FIG. 1, rack 102a is shown with secondary coolant supply 132 being delivered to each of server trays 104 of rack 102a in parallel. In various embodiments, secondary coolant loop 130 can deliver the secondary coolant to one or more of racks 102 and/or one or more of server trays 104 in parallel.

Although server trays 104 are shown separate from racks 102 in FIG. 2, it is understood that server trays 104 may be installed within racks 102 and thus may be considered components of racks 102 in some embodiments. The separate depiction of racks 102 and server trays 104 in FIG. 2 is intended to illustrate that the air cooling system (e.g., air cooler 108, fans 109 and 112, dampers 103 and 105, etc.) may provide cooled air supply 114 directly to one or more of server trays 104 (e.g., directly from cold aisle 146) without first requiring cooled air supply 114 to enter the racks 102 within which such server trays 104 are contained. For example, one or more of server trays 104 may have a cooled air intake located along an edge or surface of racks 102 adjacent to cold aisle 146 and configured to receive cooled air supply 114 directly from cold aisle 146 (e.g., via dampers 105). Accordingly, the amount of cooling provided to each of server trays 104 by the air cooling system can be independently adjusted by controlling the airflow rate of cooled supply air 114 and/or the temperature of cooled supply air 114 provided to each of server trays 104 individually. Other server trays 104 may be located within a shared volume within racks 102 and configured to receive cooled air supply 114 after cooled air supply 114 enters racks 102. For example, racks 102 may include dampers 103 which can be operated to control the flow rate of cooled air supply 114 into each of racks 102 individually. In racks 102 with a single large compartment containing multiple server trays 104, cooled air supply 114 may pass across or through multiple server trays 104 within a given rack 102 after entering the rack 102 (e.g., via dampers 103).

Although AI rack 102a is the only type of racks 102 shown in FIG. 1 as receiving the secondary coolant directly from secondary coolant loop 130 to each of server trays 104 within rack 102a, it is contemplated that any of racks 102 can be connected to secondary coolant loop 130 at the server tray level (i.e., with a separate coolant inlet and outlet for each of server trays 104 within the rack) and that such connectivity is not limited to racks 102 designated as AI racks. For example, any of CPU rack 102b and/or GPU racks 102c can also or alternatively be connected to secondary coolant loop 130 at the server tray level in various embodiments. Similarly, while CPU rack 102b and GPU racks 102c are the only type of racks 102 shown in FIG. 1 with a single coolant inlet and single coolant outlet connecting to secondary coolant loop 130, it is contemplated that any of racks 102 can be connected to secondary coolant loop 130 at the rack level (i.e., with a single coolant inlet and outlet for the rack as a whole) and that such connectivity is not limited to racks designated as CPU racks or GPU racks. For example, AI rack 102a can also or alternatively be connected to secondary coolant loop 130 at the rack level in some embodiments.

In some embodiments, primary coolant loop 120 and/or secondary coolant loop 130 supply a liquid coolant (e.g., water, glycol, etc.) to racks 102, server trays 104, and/or to individual heat-generating components installed on server trays 104 (e.g., CPUs, GPUs, etc.) to provide targeted cooling to such components. However, it is contemplated that data center cooling system 100 is not limited to using liquid coolants in primary coolant loop 120 and/or secondary coolant loop 130, but rather can use any of a variety of fluid coolants in various embodiments (e.g., gas coolants, liquid coolants, vapor coolants, mixed phase (liquid/vapor, liquid/gas) coolants, and/or any other type of fluid coolant). Accordingly, it should be understood that all references to liquid coolants throughout the present disclosure including the claims presented herein can be replaced with any other type of fluid coolant without departing from the teachings of the present disclosure.

Referring now to FIG. 3, one of racks 102 is shown in greater detail, according to an exemplary embodiment. Rack 102 is shown to include several compartments 172a, 172b, 172c, and 172d (collectively compartments 172) containing different types of server trays 104 and a power distribution unit (PDU) 176. In particular, compartments 172a are shown containing AI trays 104a, compartments 172b are shown containing GPU trays 104b, compartment 172c is shown containing CPU tray 104c, and compartment 172d is shown containing PDU 176. As noted above, the types of server trays 104 within compartments 172 may correspond to the types of computing applications run by server trays 104 and/or the types of computing devices located on server trays 104 (e.g., AI applications, high performance computing applications, GPUs, CPUs, DIMMS, etc.).

In some embodiments, compartments 172 are fluidly isolated from each other (e.g., by solid surfaces within racks 102 forming upper and lower boundaries of compartments 172) such that the airflow streams through compartments 172 do not mix with each other within racks 102. Accordingly, each of compartments 172 may receive a separate stream of cooled air supply 114 from cold aisle 146 for use in cooling the heat-producing data center equipment therein. The streams of cooled air supply 114 may be kept separate from each other within racks 102 such that each stream of cooled air supply 114 cools a corresponding compartment 172. In other embodiments, racks 102 may not include compartments 172 (or one or more of compartments 172 may be joined into a larger compartment) such that some or all of the internal volume within racks 102 is fluidly connected. In such an embodiment, racks 102 may receive one or more streams of cooled air supply 114 from cold aisle 146 and may allow the streams of cooled air supply 114 to mix or join within racks 102.

In some embodiments, racks 102 include inlet dampers 168 positioned at the cold air intake of racks 102 (e.g., between cold aisle 146 and compartments 172). Inlet dampers 168 may be aligned with compartments 172 and individually operated to independently control the flow of cooled air supply 114 into and through each of compartments 172. Dampers 103 and 105 shown in FIG. 2 may be types of inlet dampers 168 shown in FIG. 3. Similarly, racks 102 may include inlet dampers 168 positioned at the hot air exhaust of racks 102 (e.g., between compartments 172 and the hot aisle or data center room 107). Outlet dampers 170 may be aligned with compartments 172 and individually operated to independently control the flow of cooled air supply 114 out of and through each of compartments 172. Although compartments 172 are shown equipped with both inlet dampers 168 and outlet dampers 170 in FIG. 3, it is contemplated that such an arrangement may be redundant and that only one of inlet dampers 168 or outlet dampers 170 may be installed and used to control the airflow through each of compartments 172 in some embodiments. Alternatively, both inlet dampers 168 and outlet dampers 170 may be installed and used to control the airflow through compartments 172 in some embodiments.

In some embodiments, cooled air supply 114 within cold aisle 146 is maintained at an air pressure above the air pressure within data center room 107 such that the pressure differential causes cooled air supply 114 to flow through compartments 172 when inlet dampers 168 and/or outlet dampers 170 are open. For example, air cooler 108 and/or fan 112 may be operated to maintain cold aisle 146 at a positive air pressure relative to the air pressure within data center room 107. In some embodiments, racks 102 include fans 165 positioned within each compartment 172 (e.g., upstream or downstream of server trays 104). Fans 165 can be operated to independently control the flow rate of cooled air supply 114 through each of compartments 172 to provide different air flow rates to different server trays 104 within a given rack 102.

For racks 102 that contain multiple compartments 172, each compartment 172 may be equipped with an inlet damper 168, outlet damper 170, and/or fan 165. These components can be operated to independently control the flow rate of cooled air supply 114 through each compartment 172, and thus modulate the amount of cooling provided to each of server trays 104 by cooled air supply 114. For racks 102 that do not contain multiple compartments 172, such racks 102 may include one or more of inlet dampers 168, outlet dampers 170, and/or fans 165 which can be operated to control the flow rate of cooled air supply 114 through the rack 102 as a whole. In this way, each rack 102 can be provided with a different amount of air cooling either at the rack level or at the server tray level. In some embodiments, inlet dampers 168 and/or outlet dampers 170 can be replaced with vents or held permanently open to provide the same functionality as a vent. In such embodiments, airflow through each of compartments 172 can be controlled by operating fans 165 and/or by controlling the air pressure within cold aisle 146.

Still referring to FIG. 3, rack 102 is shown to include valves 166. Valves 166 may be located along secondary coolant loop 130 and operated to control the flow of the secondary coolant through rack 102 and/or server trays 104. In various embodiments, valves 166 can be located along secondary coolant supply 132 (e.g., upstream of server trays 104), along secondary coolant return 134 (e.g., downstream of server trays 104), or in both locations as shown in FIG. 3. However, it is contemplated that positioning valves 166 both upstream and downstream of server trays 104 may be redundant and that only one of an upstream valve 166 or a downstream valve 166 may be required to control the flow of the secondary coolant through rack 102 and/or server trays 104. In some embodiments, rack 102 includes one or more valves 166 within each of compartments 172 or otherwise positioned to control the flow of the secondary coolant to each of server trays 104 individually. Such an arrangement allows each of server trays 104 to receive a different flow rate of the secondary coolant from secondary coolant supply 132 (e.g., by operating valves 166) to modulate the amount of liquid cooling provided to each of server trays 104 independently. Although not explicitly shown in FIG. 3, it is contemplated that PDU 176 may also be cooled by secondary coolant loop 130 and may receive a flow of secondary coolant supply 132 in some embodiments.

In some embodiments, valves 166 and/or valves 133 can be operated to open or close different branches of secondary coolant loop 130. For example, valves 133 shown in FIG. 2 can be closed to prevent the secondary coolant from flowing into and through one or more of racks 102 or server trays 104 connected in series with valves 133, or opened to allow the secondary coolant to flow through into and through one or more of racks 102 or server trays 104 connected in series with valves 133. Similarly, valves 166 shown in FIG. 3 can be opened or closed to allow the secondary coolant to flow through individual server trays 104 within a given rack 102 while preventing the secondary coolant from flowing through other server trays 104 within a given rack 102. Valves 166 and 133 can be modulated between fully open positions and fully closed positions (i.e., set to any position between and including fully open and fully closed) to selectively control the amount of proportion of the secondary coolant that flows through each of racks 102 and/or server trays 104. In this way, the flow of the secondary coolant can be controlled (e.g., increased, decreased, etc.) or cut-off entirely to some or all of racks 102 or server trays 104 based on their individual cooling requirements. In some embodiments, valves 166 and 133 can be closed to allow some racks 102 or server trays 104 to be disconnected from secondary coolant loop 130 (e.g., for maintenance, replacement, etc.). Valves 166 and 133 can also or alternatively be closed to increase the efficiency of pump 131 by preventing pressure losses within secondary coolant loop 130 caused by pumping the secondary coolant through racks 102 or server trays 104 that do not require liquid cooling.

Referring now to FIG. 4, one of server trays 104 is shown in greater detail, according to an exemplary embodiment. Server tray 104 is shown to include a surface 152 (e.g., a bottom surface, a board, a substrate, etc.) on which one or more heat-generating components 164 are mounted or installed. Heat-generating components 164 may include any type of computing device or other data center component that generates heat during operation (e.g., CPUs, GPUs, ASICs, DIMMs, power supplies, etc.). Server tray 104 is shown to include cold plates 162 thermally coupled to heat-generating components 164 (e.g., positioned on or near heat-generating components 164 to facilitate heat transfer between cold plates 162 and heat-generating components 164) and configured to absorb heat from heat-generating components 164 during operation. Cold plates 162 may include heat sinks, tubes, liquid-to-solid heat exchangers, or any other structure configured to draw heat away from heat-generating components 164. Cold plates 162 may receive flows of the secondary coolant from secondary coolant loop 130 and transfer heat from heat-generating components 164 into the secondary coolant.

Server tray 104 is shown to include a front surface 154 having a coolant inlet port 148 and a coolant outlet port 150. Coolant inlet port 148 may be connected to secondary coolant supply 132 and may receive a flow of the chilled secondary coolant from secondary coolant loop 130. The chilled secondary coolant may flow from coolant inlet port 148 into a coolant supply header 156. Coolant supply header 156 may be connected to each of cold plates 162 via coolant lines 160 and may deliver the chilled secondary coolant to cold plates 162. The secondary coolant absorbs heat from cold plates 162 and thus provides cooling to heat-generating components 164 thermally coupled to cold plates 162. The warmed secondary coolant then flows from cold plates 162 into coolant return header 158 via coolant lines 160. Coolant return header 158 may be fluidly coupled with coolant outlet port 150 and configured to discharge the warmed secondary coolant back to secondary coolant loop 130 via coolant outlet port 150.

In some embodiments, cold plates 162 also or alternatively include fins, plates, solid-to-air heat exchangers, or other structures configured to transfer heat from cold plates 162 into cooled air supply 114 flowing across server tray 104. Cooled air supply 114 may flow across server tray 104 and absorb heat from heat-generating components 164 either directly or via cold plates 162. The warmed airflow may then exit server tray 104 via front surface 154 through outlet damper 170 and/or a front vent in various embodiments.

Referring generally to FIGS. 1-4, data center cooling system 100 may include a variety of sensors (e.g., temperature sensors, flow rate sensors, pressure sensors, etc.) positioned to measure the temperatures, flow rates, pressures, or other conditions of the airflow and liquid coolant at various locations within data center cooling system 100. For example, data center cooling system 100 may include air sensors positioned at the inlet or outlet of air cooler 108 (e.g., upstream or downstream of the heat exchanger within air cooler 108), within under-floor plenum 166, at the air inlet or outlet of each rack 102 (e.g., upstream or downstream of server trays 104), at the air inlet or outlet of each of compartments 172 (e.g., proximate to inlet dampers 168 or outlet dampers 170), within compartments 172, within data center room 107, or otherwise within the data center to measure the temperatures, flow rates, pressures, and/or other conditions of the airflow at the locations of the air sensors. For example, data center cooling system 100 may include flow rate sensors and/or temperature sensors configured to measure the flow rate or temperature of cooled air supply 114 entering each of racks 102 or each of compartments 172 and/or the flow rate or temperature of hot air return 142 exiting each of racks 102 or each of compartments 172 independently.

Data center cooling system 100 may include liquid coolant or refrigerant sensors positioned at the coolant inlets or outlets of chillers 110 (e.g., along primary coolant loop 120 upstream or downstream of evaporator 115), at any location within refrigeration circuit 111, at the coolant inlets or outlets of CDU 106 (e.g., along primary coolant loop 120 upstream or downstream of CDU 106, along secondary coolant loop 130 upstream or downstream of CDU 106), at the inlets or outlets of individual racks 102 or server trays 104 (e.g., along secondary coolant supply 132 or secondary coolant return 134), or immediately upstream or downstream of individual heat-generating components 164 within server trays 104 to measure the temperatures, flow rates, pressures, and/or other conditions of the liquid coolant or refrigerant at the locations of the liquid coolant or refrigerant sensors. For example, data center cooling system 100 may include flow rate, pressure, or temperature sensors configured to measure the flow rate, pressure, or temperature of the primary coolant entering or exiting chillers 110 (e.g., position upstream or downstream of chillers 110 along primary coolant loop 120), the secondary coolant entering or exiting CDU 106 (e.g., along secondary coolant loop 130 upstream or downstream of CDU 106), the secondary coolant entering or exiting racks 102 or server trays 104 (e.g., along secondary coolant loop 130 upstream or downstream or racks 102 or server trays 104), the refrigerant in refrigeration circuit 111 (e.g., between any of condenser 113, expansion valve 119, evaporator 115, and compressor 117), along condenser water loop 144 upstream or downstream of chillers 110, or otherwise positioned to measure any variable state or condition of the refrigerant, primary coolant, secondary coolant, or condenser water any ant location in data center cooling system 100.

In some embodiments, data center cooling system 100 includes temperature sensors configured to measure the temperatures of heat-generating components 164 (e.g., CPU temperatures, GPU temperatures, etc.). Such temperature sensors may be integrated with heat-generating components 164 (e.g., internal thermocouples or other built-in temperature sensors) or additional components of data center cooling system 100 installed to measure the temperatures at or near each of heat-generating components 164. In some embodiments, data center cooling system 100 includes power sensors configured to measure the amount of power delivered to each of racks 102, server trays 104, heat-generating components 164, or other computing devices within the data center. In some embodiments, the power sensors are implemented as wattage sensors, current sensors, or voltage sensors configured to measure the amount of electric power delivered to various components of the data center or measure variables from which power can be derived (e.g., voltage, current, etc.).

Referring particularly to FIG. 2, data center cooling system 100 is shown to include a controller 126. Controller 126 is shown to include a processing circuit 127 and a communications interface 128. Processing circuit 127 may include one or more processors and memory. The processors (shown in subsequent figures as processor 222) may include one or more general purpose or specific purpose processors, application specific integrated circuits (ASIC), one or more field programmable gate arrays (FPGAs), a group of processing components, or other suitable processing components. The processors may be configured to execute computer code or instructions stored in the memory or received from other computer readable media (e.g., CDROM, network storage, a remote server, etc.). The memory (shown in subsequent figures as memory 223) may include one or more devices (e.g., memory units, memory devices, storage devices, etc.) for storing data and/or computer code for completing and/or facilitating the various processes described in the present disclosure. The memory may include random access memory (RAM), read-only memory (ROM), hard drive storage, temporary storage, non-volatile memory, flash memory, optical memory, or any other suitable memory for storing software objects and/or computer instructions. The memory may include database components, object code components, script components, or any other type of information structure for supporting the various activities and information structures described in the present disclosure. The memory may be communicably connected to the processors via processing circuit 127 and may include computer code for executing (e.g., by the processors) one or more processes described herein.

Communications interface 128 may include wired or wireless interfaces (e.g., jacks, antennas, transmitters, receivers, transceivers, wire terminals, etc.) for conducting data communications with various systems, devices, or networks. For example, communications interface 128 may include an Ethernet card and port for sending and receiving data via an Ethernet-based communications network and/or a Wi-Fi transceiver for communicating via a wireless communications network. Communications interface 128 may be configured to communicate via local area networks or wide area networks (e.g., the Internet, a building WAN, etc.) and may use a variety of communications protocols (e.g., BACnet, IP, LON, etc.). Communications interface 128 may be configured to facilitate electronic data communications between controller 126 and various other systems or devices of data center cooling system 100 (e.g., sensors, controllable equipment, etc.) or other external data sources, systems, or devices outside data center cooling system 100. For example, controller 126 may be configured to communicate with any or all of the controllable equipment of data center cooling system 100 (e.g., CDU 106, air cooler 108, fan 109, chillers 110, fan 112, compressor 117, expansion valve 119, pump 121, valve 123, valve 125, valves 133, pump 131, dampers 103, dampers 105, inlet dampers 168, outlet dampers 170, valves 166, fans 165, etc.) and any or all of the sensors in data center cooling system 100 (e.g., any of the temperature sensors, pressure sensors, flow rate sensors, power sensors, etc.).

Controller 126 can be configured to receive measurements from the sensors and operate the controllable equipment of data center cooling system 100 to control the flow rates, pressures, temperatures, or other variable states or conditions of cooled air supply 114, hot air return 142, the refrigerant in refrigeration circuit 111, the condenser water in condenser water loop 144, the primary coolant in primary coolant loop 120, the secondary coolant in secondary coolant loop 130, or any portions thereof. In some embodiments, controller 126 receives reported values of temperatures, power consumption, or other measured or calculated variables from heat-generating components 164, PDU 176, or other data center equipment configured to report their own operating conditions (e.g., temperatures, power consumption, power delivered, computing load, etc.).

Controller 126 can use any of a variety of feedback control processes (e.g., closed-loop control, reset control, etc.), feedforward or predictive control processes (e.g., model predictive control, prediction-based control, etc.), or other control processes to operate the controllable equipment of data center cooling system 100 based on the measured values from installed sensors or reported variables from the data center equipment. Several examples of particular control processes which can be performed by controller 126 are described in detail below. Advantageously, controller 126 can be configured to precisely modulate the amount of cooling provided to each of racks 102, server trays 104, and/or individual heat-generating components 164 (referred to generally as “heat loads”) by both the air cooling equipment and the liquid cooling equipment of data center cooling system 100. Controller 126 can independently adjust the amount of cooling provided individual heat loads within the data center by controlling the air cooling equipment and the liquid cooling equipment that serve each heat load independently. This allows controller 126 to provide targeted cooling to various heat loads as needed without overcooling other heat loads more than necessary to dissipate the amount of heat generated during operation.

In some embodiments, data center cooling system 100 includes some or all of the components, features, or functionality described in U.S. Patent Application No. 17/741,108 filed May 10, 2022, U.S. Patent No. 11,497,144 granted Nov. 8, 2022, U.S. Patent Application No. 18/308,418 filed Apr. 27, 2023, U.S. Patent Application No. 18/308,422 filed Apr. 27, 2023, U.S. Patent Application No. 18/641,658 filed Apr. 22, 2024, Indian Provisional Patent Application No. 202441090506 filed Nov. 2021, 2024, U.S. Provisional Patent Application No. 63/804,615 filed May 12, 2025, U.S. Provisional Patent Application No. 63/804,544 filed May 12, 2025, U.S. Provisional Patent Application No. 63/804,546 filed May 12, 2025, U.S. Provisional Patent Application No. 63/804,553 filed May 12, 2025, and/or U.S. Provisional Patent Application No. 63/804,558 filed May 12, 2025, all of which are incorporated by reference herein in their entireties. For example, controller 126 can be configured to execute any or all of the control processes described in any of the patents, patent applications, or other documents incorporated by reference throughout the present disclosure in the context of data center cooling system 100. Data center cooling system 100 can include any or all of the equipment described in any of the aforementioned documents in various embodiments. In addition to the functionality described in these documents, controller 126 can be configured to execute a variety of new control processes that improve upon the prior art in various ways, several examples of which are described in detail below.

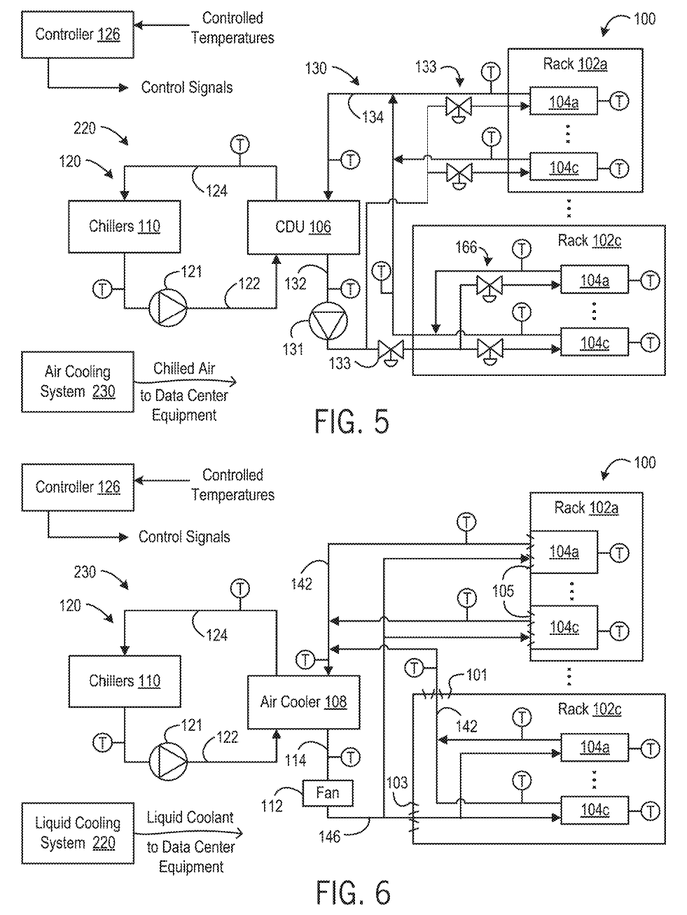

Referring now to FIGS. 5 and 6, data center cooling system 100 is shown in greater detail, according to some embodiments. FIG. 5 illustrates the fluid connections of liquid cooling system 220 including primary coolant loop 120 and secondary coolant loop 130 (referred to herein as liquid cooling loops or liquid cooling circuits). Primary coolant loop 120 circulates a primary coolant between chillers 110 and CDU 106. The primary coolant exits chillers 110 into primary coolant supply 122 and then flows into CDU 106 wherein the primary coolant absorbs heat from the secondary coolant. The primary coolant then exits CDU 106 and flows into primary coolant return 124 after absorbing heat from the secondary coolant in CDU 106. Pump 121 operates to circulate the primary coolant between chillers 110 and CDU 106 and can be located along primary coolant supply 122 and/or primary coolant return 124 in various embodiments. Temperature sensors (shown as circles containing “T” in FIGS. 5 and 6) can be located along primary coolant supply 122 and configured to measure the temperature of the primary coolant exiting chillers 110 or entering CDU 106. Temperature sensors can also or alternatively be located along primary coolant return 124 and configured to measure the temperature of the primary coolant exiting CDU 106 or entering chillers 110.

Secondary coolant loop 130 circulates a secondary coolant between CDU 106, racks 102, and/or server trays 104. The secondary coolant exits CDU 106 after rejecting heat to the primary coolant and flows into secondary coolant supply 132. Valves 133 may be located along secondary coolant supply 132 and can be operated to control the flow of the secondary coolant into each of racks 102 individually. In some embodiments, one or more of racks 102 includes additional valves 166 which can be operated to control the flow of the secondary coolant in to each of server trays 104 individually. Pump 131 operates to circulate the secondary coolant between CDU 106, racks 102, and/or server trays 104 and can be located along secondary coolant supply 132 and/or secondary coolant return 134 in various embodiments. In some embodiments, controller 126 operates CDU 106 to maintain the temperature of the liquid coolant in secondary coolant supply 132 and/or secondary coolant return 134 at or above a dew point temperature of the air within the data center to prevent condensation on liquid lines.

Temperature sensors can be located along any of secondary coolant supply 132 (e.g., at the outlet of CDU 106, at the inlets of racks 102, at the inlets of server trays 104, etc.), secondary coolant return 134 (e.g., at the inlet of CDU 106, at the outlets of racks 102 and/or server trays 104, etc.) and configured to measure the temperature of the secondary coolant at the locations of the temperature sensors. In some embodiments, secondary coolant loop 130 includes a temperature sensor located at the outlet of each of racks 102 and/or server trays 104 and configured to measure the temperatures of the secondary coolant exiting each of racks 102 and/or server trays 104. In some embodiments, data center cooling system 100 includes temperature sensors configured to measure the temperatures of each of racks 102, server trays 104, and/or individual components of data center equipment 240 (e.g., CPU temperatures, GPU temperatures, etc.).

FIG. 6 illustrates the fluid connections of air cooling system 230 including primary coolant loop 120 and an air cooling loop 232. Primary coolant loop 120 may be the same as described with reference to FIG. 5 with the exception that primary coolant loop 120 delivers the primary coolant to air cooler 108. Air cooler 108 transfers heat from the air into the primary coolant to generate cooled air supply 114. Temperature sensors can be located along primary coolant supply 122 and configured to measure the temperature of the primary coolant exiting chillers 110 or entering air cooler 108. Temperature sensors can also or alternatively be located along primary coolant return 124 and configured to measure the temperature of the primary coolant exiting air cooler 108 or entering chillers 110.

Air cooling loop 232 (e.g., an air cooling circuit) circulates air between air cooler 108, racks 102, and/or server trays 104. Cooled air supply 114 exits air cooler 108 and is circulated by fan 112 through cold aisle 146 and into racks 102 via dampers 103 and/or into server trays 104 via dampers 105. Cooled air supply 114 absorbs heat from data center equipment 240 within racks 102 and/or server trays 104 and exits racks 102 and/or server trays 104 via top vents 101 and/or dampers 105. Temperature sensors can be positioned to measure the temperature of the cooled air supply 114 exiting air cooler 108 (e.g., within cold aisle 146, at the inlets of racks 102 and/or server trays 104, etc.), the temperature of the air exiting racks 102 and/or server trays 104 (e.g., immediately downstream of racks 102 and/or server trays 104, at the outlets of racks 102 and/or server trays 104), or any other location within air cooling loop 232. In general, temperature sensors can be located at any of the positions shown in FIGS. 5 and 6 or otherwise located in liquid cooling system 220 and/or air cooling system 230 to measure the temperatures of the primary coolant, secondary coolant, cooled air, or other coolant temperatures at any location within liquid cooling system 220 and/or air cooling system 230.

Some cooling systems implemented with data centers include numerous stages of heat exchange, which may limit an overall efficiency or effectiveness of such cooling systems to transfer and reject heat generated by electronic equipment in data centers. To this end, present embodiments are directed to improved configurations of cooling systems (e.g., data center cooling systems) configured to provide cooling to electronic equipment with increased efficiency and effectiveness. For example, certain cooling systems incorporating the techniques described herein include a chiller system that operates to cool a working fluid and direct the working fluid to the electronic equipment to place the working fluid in a heat exchange relationship with the electronic equipment, such as via a chilled plate, a cold plate, a tube, a flow path, a channel, a vessel, and/or immersion cooling techniques. In such embodiments, the cooling system may not include a conditioning fluid circuit configured to place a conditioning fluid in a first heat exchange relationship with the working fluid and in a second heat exchange relationship with the electronic equipment. Instead, at least a portion of the working fluid circuit may extend from the chiller system to the electronic equipment, thereby enabling the working fluid to flow to the electronic equipment and absorb heat from the electronic equipment. Accordingly, certain embodiments discussed herein may not incorporate a CDU that includes a heat exchanger configured to enable heat transfer between two flows of fluid, such as a conditioning fluid cooled by a chiller system and a coolant placed in a heat exchange relationship with electronic equipment. Additionally, certain embodiments discussed herein may not include an evaporator of a chiller system configured to enable heat transfer between a working fluid circulated through the chiller system and a conditioning fluid placed in a heat exchange relationship with the electronic equipment. Therefore, one or more stages of heat transfer typically included in some cooling systems is omitted, which enables enhanced efficiency of the chiller system and improved (e.g., increased) rejection of heat generated by the electronic equipment.

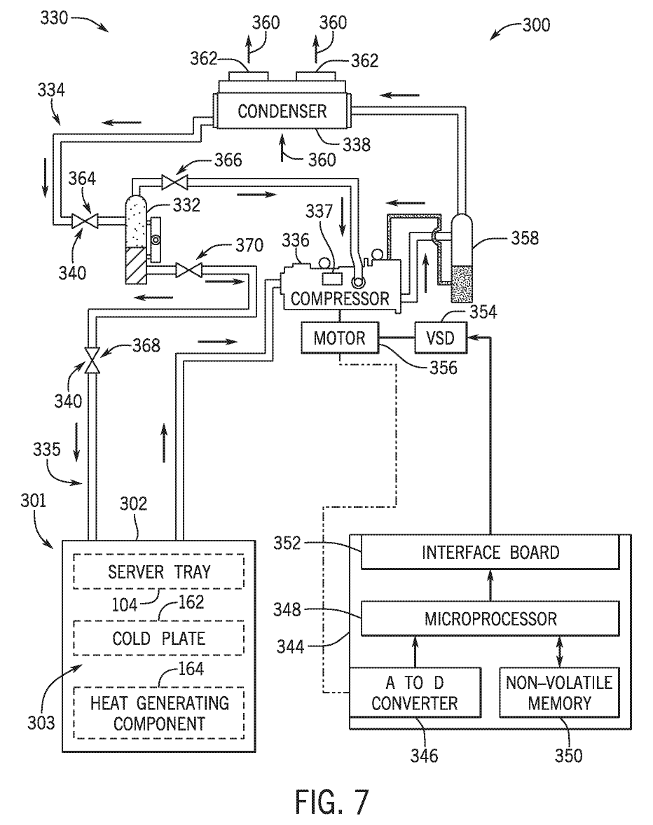

With the preceding in mind, FIG. 7 is a schematic of an embodiment of a cooling system 300 (e.g., computer cooling system, electronic equipment cooling system, data center cooling system) configured to provide cooling to electronic equipment 301 (e.g., one or more racks 102, server trays 104, and/or heat generating components 164). In certain embodiments, the electronic equipment 301 may be or include an embodiment of a computer enclosure 302 (e.g., frame, support structure) configured to house and/or support computer componentry 303 (e.g., computer components, computer chips), such as one or more server trays 104, one or more cold plates 162, one or more heat-generating components 164, or any combination thereof. Additionally, or alternatively, the electronic equipment 301 may be or include an embodiment of a rack or cabinet, such as the rack 102, configured to house and/or support multiple computer enclosures 302, each being configured to house and/or support respective computer componentry 303 (e.g., integrated circuits, circuit boards, communication circuitry, processors, servers, server trays, computer chips, memories, routers, switches, controllers, heat-generating components, and/or other computer hardware).

In the illustrated embodiment, the cooling system 300 includes a vapor compression system 330 (e.g., mechanical cooling system, air-cooled vapor compression system, chiller system, air-cooled chiller system). For example, the vapor compression system 330 may be system of an air-cooled chiller. The vapor compression system 330 includes a working fluid circuit 334 (e.g., vapor compression circuit, working fluid circuit) configured to circulate a working fluid, such as a refrigerant, therethrough with a compressor 336 (e.g., screw compressor, centrifugal compressor, compressor system) disposed along the working fluid circuit 334. The working fluid circuit 334 also includes a flash tank 332, a condenser 338 (e.g., first condenser, heat exchanger, air-cooled condenser), and expansion valves or devices 340. As shown in the illustrated embodiment, at least a portion 335 of the working fluid circuit 334 (e.g., working fluid flow path) may extend through the electronic equipment 301, thereby enabling cooling of the electronic equipment 301 via the working fluid directed along the working fluid circuit 334. The components of the working fluid circuit 334 enable heat transfer between the working fluid and other fluids (e.g., air, water) in order to provide cooling to the electronic equipment 301.

Some examples of working fluids that may be used as refrigerants in the vapor compression system 330 are hydrofluorocarbon (HFC) based working fluids, for example, R-410A, R-407, R-134a, hydrofluoro olefin (HFO), “natural” working fluids like ammonia (NH3), R-717, carbon dioxide (CO2), R-744, or hydrocarbon-based working fluids, water vapor, or any other suitable working fluid. Other possible working fluids that may be circulated through the vapor compression system 330 include R-123, R-514A, R-1224yd, R-1233zd, R-134a, R-1234ze, R-1234yf, R-1311, and R-32. In some embodiments, the vapor compression system 330 may be configured to efficiently utilize working fluids having a normal boiling point of about 19 degrees Celsius (66 degrees Fahrenheit or less) at one atmosphere of pressure, also referred to as low pressure working fluids, versus a medium pressure working fluids, such as R-134a. As used herein, “normal boiling point” may refer to a boiling point temperature measured at one atmosphere of pressure.

The vapor compression system 330 may further include a control panel 344 (e.g., a controller) that has an analog to digital (A/D) converter 346, a microprocessor 348, a non-volatile memory 350, and/or an interface board 352. In some embodiments, the vapor compression system 330 may use one or more of a variable speed drive (VSDs) 354 and a motor 356. The motor 356 may drive the compressor 336 and may be powered by the VSD 354. The VSD 354 receives alternating current (AC) power having a particular fixed line voltage and fixed line frequency from an AC power source and provides power having a variable voltage and frequency to the motor 356. In other embodiments, the motor 356 may be powered directly from an AC or direct current (DC) power source. The motor 356 may include any type of electric motor that can be powered by the VSD 354 or directly from an AC or DC power source, such as a switched reluctance motor, an induction motor, an electronically commutated permanent magnet motor, or another suitable motor.

The compressor 336 may be configured to pressurize and/or compress a working fluid vapor received from the electronic equipment 301 and may direct the working fluid vapor along the working fluid circuit 334 toward the condenser 338. In certain embodiments, the working fluid vapor may be delivered from the compressor 336 to an oil separator 358 configured to separate oil from the working fluid vapor. In such embodiments, the working fluid vapor is then directed toward the condenser 338, and the oil is returned to the compressor 336. However, in other embodiments, the compressor 336 may be an oil-less compressor (e.g., magnetic bearing compressor), and the working fluid vapor is delivered from the compressor 336 to the condenser 338 (e.g., without passing through an oil separator, such as the oil separator 358). In such embodiments, the oil separator 358 is omitted. In any case, the compressor 336 may include one or more components that form a portion of the working fluid circuit and are configured to enable pressurization of the working fluid while mitigating exposure of the working fluid to potential particulates or contaminants within the compressor 336.

For example, as mentioned above, it may be desirable to mitigate exposure of the working fluid that is directed toward the electronic equipment 301 to potential particulates or contaminants. Indeed, exposure of the working fluid to certain materials, such as materials that may be susceptible to corrosion and/or degradation (e.g., chemical or electrochemical corrosion), may cause particulates, contaminants, or other impurities to mix with (e.g., become entrained within) the working fluid before the working fluid is delivered to the electronic equipment 301. Introduction of a fluid (e.g., working fluid) having particulates, contaminants, or other impurities mixed therein to the electronic equipment 301 may cause wear and/or degradation to the electronic equipment 301, and in some cases, may cause operational disruptions of the electronic equipment 301. To this end, the compressor 336 may include a bearing system 337 having one or more bearings (e.g., magnetic bearings, primary bearings, secondary bearings, mechanical bearings) configured to limit and/or avoid an amount of metal-to-metal contact (e.g., metal-to-metal skidding) within the compressor 336, thereby reducing potential creation and/or exposure of particulates, contaminants, or impurities within the compressor 336 to the working fluid that may otherwise be created via metal-to-metal contact, as discussed in greater detail below. In this way, the working fluid directed through the compressor 336 may remain free or substantially free of particulates, contaminants, or other impurities, such that the working fluid may be suitable for placing in a heat transfer arrangement with electronic equipment 301.

The working fluid vapor delivered to the condenser 338 may transfer heat to a cooling fluid at the condenser 338. For example, the cooling fluid may be ambient air 360 forced across heat exchanger coils of the condenser 338 by condenser fans 362. The working fluid vapor may condense to a working fluid liquid in the condenser 338 as a result of thermal heat transfer with the cooling fluid (e.g., the ambient air 360). The liquid working fluid exits the condenser 338 and then flows through a first expansion device 364 (e.g., the expansion device 340, an electronic expansion valve). The first expansion device 364 may be a flash tank feed valve configured to control flow of the liquid working fluid to the flash tank 332. The first expansion device 364 is also configured to lower the pressure of (e.g., expand) the liquid working fluid received from the condenser 338. During the expansion process, a portion of the liquid may vaporize, and thus, the flash tank 332 may be used to separate the vapor from the liquid received from the first expansion device 364. Additionally, the flash tank 332 may provide for further expansion of the liquid working fluid due to a pressure drop experienced by the liquid working fluid when entering the flash tank 332 (e.g., due to a rapid increase in volume experienced when entering the flash tank 332).

The vapor in the flash tank 332 may exit and flow to the compressor 336. For example, the vapor may be drawn to an intermediate stage or discharge stage of the compressor 336 (e.g., not the suction stage). A valve 366 (e.g., an economizer valve, solenoid valve) may be included in the working fluid circuit 334 to control flow of the working fluid vapor from the flash tank 332 to the compressor 336. In some embodiments, when the valve 366 is open (e.g., fully open), additional liquid working fluid within the flash tank 332 may vaporize and provide additional subcooling of the liquid working fluid within the flash tank 332. The liquid working fluid that collects in the flash tank 332 may be at a lower enthalpy than the liquid working fluid exiting the condenser 338 due to the expansion in the first expansion device 364 and/or the flash tank 332. The liquid working fluid may flow from the flash tank 332, through a second expansion device 368 (e.g., the expansion device 340, an orifice), and to the electronic equipment 301 (e.g., via the portion 335 of the working fluid circuit 334 that extends to and from the electronic equipment 301). In some embodiments, the working fluid circuit 334 may also include a valve 370 (e.g., a drain valve) configured to regulate flow of liquid working fluid from the flash tank 332 to the electronic equipment 301. For example, the valve 370 may be controlled (e.g., via the control panel 344) based on an amount of suction superheat of the working fluid.

The liquid working fluid delivered to the electronic equipment 301 may absorb heat from the computer components 303 (e.g., chips) disposed within and/or thermally coupled to the computer enclosure 302, such that the liquid working fluid directed to the electronic equipment 301 may undergo a phase change to become working fluid vapor. For example, the working fluid circuit 334 may be configured to circulate the working fluid along the portion 335 of the working fluid circuit 334 from the flash tank 332 to the electronic equipment 301 and from the electronic equipment 301 to the compressor 336 (e.g., without an intermediate stage of heat exchange, such as via an evaporator and/or a CDU heat exchanger), thereby enabling cooling of the electronic equipment 301 via the working fluid. Said another way, the portion 335 of the working fluid circuit 334 may extend directly to the electronic equipment 301 without any intervening heat exchange components. For example, while the portion 335 may include certain valves, sensors, filters, pumps, and/or other fluid conveyance devices, the portion 335 of working fluid circuit 334 may not include a heat exchanger, such as a CDU heat exchanger, configured to exchange heat between a conditioning fluid circulated between the CDU and an evaporator and a coolant circulated between the CDU and the electronic equipment. Additionally, the working fluid circuit 334 may not include an evaporator configured to exchange heat between a working fluid circulated along the working fluid circuit and a conditioning fluid circulated between the evaporator and the electronic equipment. Thus, by extending at least the portion 335 of the working fluid circuit 334 to the electronic equipment 301, one or more stages of heat exchange and/or heat transfer included in certain systems, such as systems having a CDU heat exchanger and/or multiple coolant loops, may be omitted, which may enable operation of the computer cooling system 300 which reduced energy consumption.

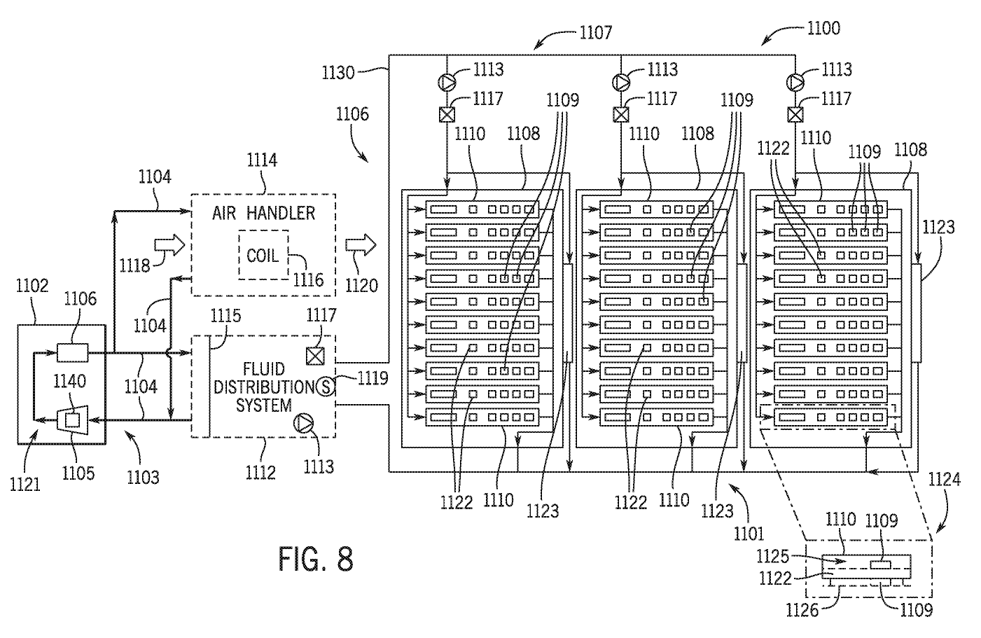

FIG. 8 is a schematic of an embodiment of a cooling system 1100 (e.g., computer cooling system, electronic equipment cooling system, data center cooling system, cooling system 300) configured to provide cooling to electronic equipment 1101. The cooling system 1100 includes a chiller system 1102 (e.g., vapor compression system 330) configured to generate (e.g., cool) a working fluid 1104 (e.g., cooling fluid, two-phase fluid, single-phase fluid) that is directed to the electronic equipment 1101 (e.g., electronic equipment 301) to cool the electronic equipment 1101. In some embodiments, the chiller system 1102 may be an air-cooled chiller. For example, the chiller system 1102 may operate in a manner similar to that described above with respect to the vapor compression system 330, and may include a working fluid circuit 1103 (e.g., working fluid circuit 334) having a compressor 1105 (e.g., compressor 336, compressor system) and one or more condensers 1106 (e.g., condenser 338, condenser coils, heat exchangers), among other components (e.g., expansion valve(s), flash tank, motor, VSD, etc.). In certain embodiments, the compressor 1105 may circulate the working fluid 1104 along the working fluid circuit 1103 (e.g., along a portion 1107 of the working fluid circuit 1103) to the electronic equipment 1101 to place the working fluid 1104 in a heat exchange relationship with the electronic equipment 1101. The working fluid 1104 may absorb heat from the electronic equipment 1101 (e.g., cool the electronic equipment 1101) and may be delivered back to the compressor 1105. In an embodiment of the chiller system 1102 configured as an air-cooled chiller, the condenser(s) 1106 may enable transfer of heat from the working fluid 1104 to ambient air, thereby cooling the working fluid 1104 and enabling rejection of heat absorbed by the working fluid 1104 from the electronic equipment 1101. However, it should be appreciated that the chiller system 1102 may include other configurations and/or components, such as a water-cooled chiller, a cooling tower, a dry cooler, another suitable component or system, or any combination thereof. In some embodiments, the cooling system 1100 may also include an air handler 1114 (e.g., air handling unit) having a heat exchanger 1116 (e.g., coil) configured to receive the working fluid 1104 to cool an air flow 1118 directed across the heat exchanger 1116 to generate a cooled air flow 1120. The cooled air flow 1120 may be directed to the electronic equipment 1101 to cool the electronic equipment 1101.

In the illustrated embodiment, the electronic equipment 1101 includes a plurality of cabinets 1108 (e.g., racks 102, server cabinet, computer cabinet, electronics cabinet), and each cabinet 1108 is configured to support a respective plurality of computer enclosures 1110 (e.g., computer enclosure 302). Each computer enclosure 1110 is configured to contain, house, and/or support one or more computer components 1109 (e.g., computer componentry 303), such as one or more server trays (e.g., server trays 104), computer chips, integrated circuits, circuit boards, communication circuitry, processors, servers, memories, routers, switches, controllers, heat-generating components (e.g., heat-generating components 164), and/or other computer hardware. In some embodiments, one or more of the cabinets 1108 may be a computer server rack, a computer equipment rack, a server rack, a server chassis, or other suitable structure configured to support one or more of the computer enclosures 1110. The computer enclosures 1110 may include a rack server enclosure, a server tray enclosure, a blade server enclosure, another suitable enclosure configured to contain electronic components, or any combination thereof. The cabinets 1108 may be disposed within an embodiment of a building configured as a data center.

During operation, the electronic equipment 1101 may generate heat, which may cause a temperature of the computer components 1109 within and/or thermally coupled to the computer enclosures 1110 to increase. It is desirable to maintain the temperature of the computer components 1109 disposed within and/or thermally coupled to the computer enclosures 1110 below applicable temperature thresholds in order to enable proper operation of the computer components 1109 and avoid operational interruptions. Accordingly, present embodiments include the cooling system 1100 configured to supply the working fluid 1104 to the cabinets 1108 and/or the computer enclosures 1110 to absorb heat generated by the computer components 1109 and reject the heat to another suitable location or environment.

As will be appreciated, some systems utilized to cool computer components and/or electronic equipment may include an HVAC&R system having a working fluid circuit, a conditioning fluid circuit configured to circulate a conditioning fluid, and a coolant circuit configured to circulate a coolant. During operation of such systems, the working fluid circuit (e.g., refrigeration circuit 111) and the conditioning fluid circuit (e.g., primary coolant loop 120) may be in a heat exchange relationship to enable transfer of heat from the conditioning fluid to the working fluid, while the conditioning fluid circuit and the coolant circuit (e.g., secondary coolant loop 130) may be in a heat exchange relationship to enable transfer of heat from the coolant fluid to the conditioning fluid. For example, such systems may include a coolant distribution unit (CDU) (e.g., CDU 106) having a heat exchanger configured to establish a heat exchange relationship between the conditioning fluid circuit and the coolant circuit. The coolant circuit may extend from the CDU to the computer equipment to place the coolant in a heat exchange relationship with the computer equipment in order to absorb heat generated by the computer equipment. However, such systems include numerous stages of heat transfer (e.g., between multiple fluids) between the working fluid circuit and the computer equipment, which limits overall efficiency and/or effectiveness of heat rejection, as mentioned above.

Various embodiments of the cooling system 1100, in accordance with the present techniques, do not include a CDU having a heat exchanger configured to place a conditioning fluid and a coolant in a heat exchange relationship. Present embodiments also may not include a separate coolant circuit and/or a conditioning fluid circuit in addition to the working fluid circuit 1103 of the chiller system 1102. Further still, present embodiments also may not include an evaporator positioned along the working fluid circuit 1103. Instead, the cooling system 1100 is configured to circulate the working fluid 1104 along the working fluid circuit 1103 between aspects of the chiller system 1102 (e.g., the compressor 1105 and/or the compressors 1106 of the chiller system 1102) and the electronic equipment 1101 (e.g., cabinets 1108, computer enclosures 1110). Thus, the working fluid circuit 1103 may place the working fluid 1104 in a heat exchange relationship with the computer components 1109 disposed within and/or thermally coupled to the computer enclosures 1110, as described in greater detail below. For example, the working fluid circuit 1103 may include one or more flow paths that extend within the cabinets 1108 and/or within one or more of the computer enclosures 1110. In certain embodiments, the working fluid 1104 may be circulated through the computer enclosure 1110, such as via a tube, conduit, flow path, channel, vessel, chilled plate, cold plate, immersion cooling techniques (e.g., direct contact with one or more computer components 1109), or any combination thereof. In this way, one or more stages of heat transfer typically included in certain systems may be omitted, which may enable operation of the chiller system 1102 with reduced energy consumption.

In some embodiments, the cooling system 1100 (e.g., the working fluid circuit 1103) may also include a fluid distribution system 1112 configured to enable distribution of the working fluid 1104 to the electronic equipment 1101 (e.g., to each cabinet 1108, to each computer enclosure 1110). The working fluid circuit 1103 and/or the fluid distribution system 1112 may include one or more components, such as one or more pumps 1113, filters 1115, valves 1117, sensors 1119, bypass conduits, and so forth that enable selective distribution of the working fluid 1104 to the electronic equipment 1101. For example, the fluid distribution system 1112 may include one or more sensors 1119 configured to detect a parameter indicative of a quality or characteristic of the working fluid 1104 (e.g., particle concentration, chemical component) directed to the cabinets 1108 and/or computer enclosures 1110. In some embodiments, the fluid distribution system 1112 may include an in-line spectrometry sensor disposed along the working fluid circuit 1103.

The fluid distribution system 1112 may include certain components associated with a respective one of the cabinets 1108. For example, the fluid distribution system 1112 may include multiple pumps 1113 and/or valves 1117 configured to service (e.g., regulate flow of the working fluid 1104) to one or more of the cabinets 1108 and/or computer enclosures 1110. In certain embodiments, each cabinet 1108 and/or computer enclosure 1110 may be associated with a corresponding pump 1113 and/or valve 1117. Further, in certain embodiments, one or more of the valves 1117 may correspond to an expansion device (e.g., expansion device 368) configured to decrease the pressure of the working fluid 1104 before delivering the working fluid 1104 to the electronic equipment 1101. As will be appreciated, the cooling system 1100 may include any number of pumps 1113 and/or valves 1117 to enable selective distribution of the working fluid 1104 to the electronic equipment 1101 (e.g., to each of the cabinets 1108 and/or computer enclosures 1110). In this way, components of the fluid distribution system 1112 (e.g., pumps 1113, valves 1117) may be actuated to suspend flow of the working fluid 1104 to one of the cabinets 1108 and/or computer enclosures 1110, while enabling flow of the working fluid 1104 to remaining cabinets 1108 and/or computer enclosures 1110. In some embodiments, the fluid distribution system 1112 may be configured to regulate flow of a respective portion of the working fluid 1104 to each computer enclosure 1110 disposed within the cabinet 1108 (e.g., via corresponding valves 1117 associated with each computer enclosure 1110).

In some embodiments, the fluid distribution system 1112 may include one or more filters 1115 (e.g., permeable membrane) configured to enable flow of the working fluid 1104 therethrough and to capture one or more particles and/or contaminants within the flow of working fluid 1104. One or more of the components of the fluid distribution system 1112 may be contained in a dedicated housing or unit, distributed along the working fluid circuit 1103 at other locations, integrated within one or more of the cabinets 1108, integrated with the chiller system 1102, or any combination thereof.

In certain embodiments, the portion 1107 of the working fluid circuit 1103 that extends to the electronic equipment 1101 (e.g., extends through one or more of the cabinets 1108) may be defined by any suitable component(s) disposed within and/or thermally coupled to the cabinet 1108. Said another way, the portion 1107 of the working fluid circuit 1103 may be at least partially defined by one or more of the cabinets 1108, one or more of the computer enclosures 1110, a cold plate 1122 (e.g., heat exchanger, chilled plate) coupled to or disposed within one or more of the computer enclosures 1110, a heat exchanger 1123 (e.g., rear door heat exchanger) disposed within the cabinet 1108, or any combination thereof. Indeed, as shown in FIG. 8, a heat exchange interface 1124 between the working fluid 1104 and the computer component 1109 may take any of various forms, including direct immersion of the computer component 1109 in the working fluid 1104, direct and/or thermal contact between the component 1109 and an embodiment of the cold plate 1122 (e.g., heat exchanger) configured to receive the working fluid 1104, or a combination thereof.

For example, in certain embodiments, the computer component 1109 may be positioned within an interior volume 1125 (e.g., pressure vessel) defined by the computer enclosure 1110. The interior volume 1125 of the computer enclosure 1110 may correspond to a pressure vessel configured to receive the working fluid 1104, such that the computer component 1109 disposed therein is immersed in the working fluid 1104 and cooled via immersion cooling techniques. In other embodiments, the computer enclosure 1110 may include the cold plate 1122 (e.g., heat exchanger, chilled plate) disposed within the interior volume 1125 and operable to receive the working fluid 1104. The cold plate 1122 may be engaged with (e.g., thermally coupled to, directly coupled to) the computer component 1109 to facilitate heat exchange between the working fluid 1104 and the computer component 1109. In still other embodiments, the computer component 1109 may be positioned external to the computer enclosure 1110 and may be thermally coupled to the cold plate 1122 to enable heat exchange between the working fluid 1104 and the computer component 1109. For example, in certain embodiments, the computer enclosure 1110 may correspond to a frame or enclosure configured to support one or more cold plates 1122. In such embodiments, an additional support structure, such as a server tray 1126 having one or more computer components 1109 disposed thereon, may be mounted to the computer enclosure 1110 such that the one or more computer components 1109 engage with (e.g., thermally engage with) the one or more cold plates 1122 supported by the computer enclosure 1110. In any case, the computer component 1109 may be placed in a heat exchange relationship with the working fluid 1104 of the chiller system 1102 via the heat exchange interface 1124, thereby enabling the working fluid 1104 to absorb heat from (e.g., cool) the computer component 1109.

Additionally, or alternatively, one or more of the cabinets 1108 may include the heat exchanger 1123. The heat exchanger 1123 may be configured to transfer heat from within the cabinet 1108 (e.g., heat generated by the electronic equipment 1101 within the cabinet 1108) to the working fluid 1104 directed through the heat exchanger 1123. For example, in certain embodiments, air (e.g., ambient air, room air) may be directed through and/or across the electronic equipment 1101 (e.g., computer enclosures 1110 and/or computer components 1109) to absorb heat from the electronic equipment 1101. In embodiments in which the heat exchanger 1123 is configured as a rear door heat exchanger, the heat exchanger 1123 may be positioned within a respective cabinet 1108 supporting the electronic equipment 1101. In certain embodiments, the heat exchanger 1123 may be positioned downstream of the electronic equipment 1101 (e.g., relative to a flow direction of the air flow across the electronic equipment 1101). The heat exchanger 1123 may circulate the working fluid 1104 therethrough, thereby enabling the air flow to transfer heat to the working fluid 1104. In any case, the portion 1107 of the working fluid circuit 1103 may enable transfer of heat from within the cabinet 1108 (e.g., transfer of heat generated by the computer components 1109 within the cabinet 1108) to the working fluid 1104 directed along the working fluid circuit 1103. After absorbing heat from the electronic equipment 1101, the working fluid 1104 may be directed along an additional portion 1121 of the working fluid circuit 1103 defined at least in part by the compressor 1105 and the condensers 1106, thereby enabling rejection of the heat and cooling of the working fluid 1104 (e.g., via thermal heat transfer with a cooling fluid, such as ambient air, directed across the condensers 1106).

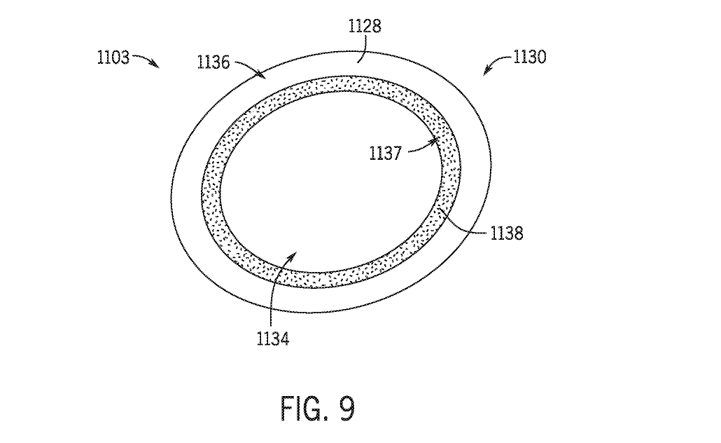

As mentioned above, to avoid operational disruptions of the electronic equipment 1101, the working fluid 1104 directed along the working fluid circuit 1103 (e.g., along the portion 1107 and/or the portion 1121) should be maintained to remain free or substantially free of contaminants, particulates, and/or other impurities that may otherwise affect operation of the electronic equipment 1101. Exposure of the working fluid 1104 to certain materials, such as materials that may be susceptible to chemical or electrochemical corrosion, should therefore be avoided. Thus, in certain embodiments, one or more components defining the working fluid circuit 1103 may be formed from materials that are not susceptible to chemical or electrochemical corrosion or degradation. For example, piping 1130 of the working fluid circuit 1103 may be formed from a material such as stainless steel or plastic. In some embodiments, the piping 1130 may include plastic-lined piping. For example, as shown in FIG. 9, the piping 1130 may include a body 1132 that defines a flow path 1134 (e.g., interior volume) for the working fluid 1104 to flow along the piping 1130. In certain embodiments, the body 1132 may be defined by and/or may be formed from a first material 1136, and an interior 1137 (e.g., inner diameter, inner surface, working fluid contacting surface) of the body 1132 may be lined with a second material 1138, whereby the second material 1138 is a non-corrosive material, such as plastic, copper, stainless steel, or the like. In other embodiments, the body 1132 may be formed from the second material 1138. In any case, the second material 1138 may be configured to limit exposure of the working fluid 1104 to certain materials that may be susceptible to chemical or electrochemical corrosion.

Returning to FIG. 8, metal-to-metal contact (e.g., metal-to-metal skidding) between components of the chiller system 1102 (e.g., components of the compressor 1105) should also be avoided. For example, as noted above, metal-to-metal contact between components of the compressor 1105 may be associated with the generation or creation of particulates, contaminants, or impurities that may be entrained within a working fluid flow directed through the compressor 1105 and toward the electronic equipment 1101. To this end, the compressor 1105 may include one or more components, such as components that may contact one another and to which the working fluid 1104 may be exposed, that are configured to limit or reduce an amount of metal-to-metal contact within the compressor 1105. For example, the compressor 1105 may include a bearing system 1140 (e.g., bearing system 337) having one or more primary bearings and one or more backup bearings. The primary bearings may include magnetic bearings configured to impart magnetic forces onto a shaft of the compressor 1105 to enable desired positioning and/or support (e.g., levitation) of the shaft during operation of the compressor 1105. Thus, during operation, the primary bearings of the bearing system 1140 may be configured to limit or reduce metal-to-metal contact within the compressor.

The backup bearings may include ball bearings (e.g., angular contact ball bearings, deep groove ball bearings) having raceways (e.g., inner raceway, outer raceway) and a number of ball bearings positioned between the raceways to enable movement of the raceways relative to one another. The backup bearings, or at least a portion thereof configured to contact (e.g., directly contact) the shaft of the compressor (e.g., during operational interruption of the primary bearings, during an inoperative mode of the compressor 1105), may be formed of a non-conductive material (e.g., non-metallic material, ceramic, silicon nitride, zirconium dioxide). By utilizing a non-conductive material to form at least a portion of the backup bearings that is configured to directly contact the shaft of the compressor 1105, metal-to-metal contact within the compressor 1105 may be reduced and/or avoided (e.g., during operational interruption of the primary bearings, during an inoperative mode of the compressor 1105), thereby reducing formation of particulates, contaminants, or impurities within the compressor 1105. In this way, the working fluid 1104 directed through the compressor 1105 may remain free or substantially free of particulates, contaminants, or other impurities, such that the working fluid 1104 may be suitable for placing in a heat transfer arrangement with the electronic equipment 1101, as described in greater detail below.

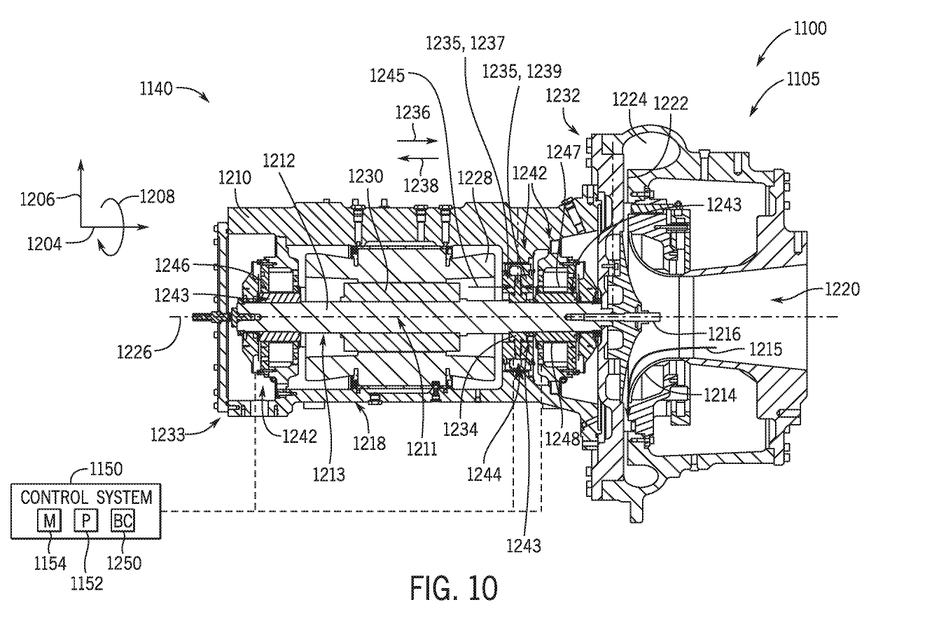

With the foregoing in mind, FIG. 10 is a cross-sectional side view of an embodiment of the compressor 1105, illustrating features of an embodiment of the bearing system 1140. To facilitate the following discussion, the compressor 1105 and components thereof may be described with reference to a longitudinal axis or direction 1204, a radial axis or direction 1206 (e.g., lateral axis or direction, cross-wise to the longitudinal axis or direction 1204), and a circumferential direction 1208. It should be appreciated that the radial axis or direction 1206 may extend radially outward, relative to the longitudinal axis 1204, in any suitable direction.

The compressor 1105 includes a housing 1210 and a shaft 1212 extending through the housing 1210. The compressor 1105 also includes an impeller 1214 coupled to the shaft 1212, such as via a fastener 1216. During operation of the compressor 1105, the shaft 1212 may rotate, via operation of a motor 1218 (e.g., motor 356), and cause rotation of the impeller 1214 within the housing 1210. Rotation of the impeller 1214 may drive a working fluid (e.g., working fluid 1104, refrigerant) to flow through a working fluid flow path 1215 to draw the working fluid into the housing 1210 via a suction inlet 1220 of the compressor 1105 and toward the impeller 1214. The impeller 1214 may impart mechanical energy to the working fluid and discharge the working fluid toward a diffuser passage 1222 of the compressor 1105 via an impeller exit or outlet of the impeller 1214. The working fluid may be directed from the diffuser passage 1222 to a volute 1224 of the compressor 1105. Thereafter, the compressor 1105 may drive the working fluid to flow along a working fluid circuit (e.g., working fluid circuit 1103, working fluid circuit 334) to another component of the cooling system 1100 (e.g., the condenser 1106) for heat exchange with a fluid, such as a cooling fluid.

As mentioned above, the motor 1218 is coupled to the shaft 1212 and is configured to drive rotation of the shaft 1212 about a rotational axis 1226 of the shaft 1212 during operation of the compressor 1105 to enable rotation of the impeller 1214. To this end, the motor 1218 includes a stator 1228 and a rotor 1230 (e.g., positioned about a longitudinal center 1211 of the shaft 1212. As will be appreciated, the rotor 1230 may be securely fastened or attached to the shaft 1212, and the stator 1228 may be a stationary component that extends circumferentially (e.g., in the circumferential direction 1208) about the rotor 1230. In certain embodiments, the rotor 1230, or at least a portion thereof that contacts the shaft 1212 (e.g., outer surface 1213 of the shaft 1212), may be formed of a non-conductive material, thereby limiting metal-to-metal contact within the compressor 1105. For example, an interior surface of the rotor 1230 configured to engage with and the outer surface 1213 the shaft 1212 may include and/or be lined with a non-conductive material (e.g., ceramic, silicon nitride, zirconium dioxide). The stator 1228 may impart radial and axial magnetic forces onto the rotor 1230 to drive rotation of the rotor 1230 and thereby drive rotation of the shaft 1212 and the impeller 1214.

In the illustrated embodiment, the compressor 1105 (e.g., the motor 1218) includes an embodiment of the bearing system 1140 configured to limit, reduce, and/or avoid an amount of metal-to-metal contact (e.g., metal-to-metal skidding) in the compressor 1105 while supporting and enabling rotation of the shaft 1212. The bearing system 1140 may include a plurality of bearings (e.g., bearing assemblies, primary bearing assemblies, magnetic bearing assemblies, backup bearing assemblies, ball bearing assemblies) disposed circumferentially (e.g., in the circumferential direction 1208) about the shaft 1212. In certain embodiments, one or more of the bearings of the bearing system 1140 may correspond to (e.g., be, include) primary bearings 1242 configured to control and/or adjust a position of the shaft 1212 relative to the axis 1226, whereas other bearings of the bearing system 1140 may correspond to (e.g., be, include) backup bearings 1243 configured to support and enable rotation of the shaft 1212, such as during instances in which operation of the primary bearings 1242 is inadvertently (e.g., unexpectedly) interrupted and/or otherwise adversely impacted.

In certain embodiments, each of the primary bearings 1242 may include a magnetic bearing configured to impart forces onto the shaft 1212 to enable desired positioning and/or support of the shaft 1212 during operation of the compressor 1105. In some embodiments, one or more of the primary bearings 1242 may be active magnetic bearings having actuators and/or other features configured to continuously and/or continually receive and/or adjust a current supplied to the primary bearings to adjust and/or maintain a position of the shaft 1212 during rotation. As shown, the primary bearings 1242 include a first primary bearing 1244 (e.g., thrust bearing, axial bearing, magnetic thrust bearing) configured to control and/or adjust a position (e.g., axial position) of the shaft 1212 along the rotational axis 1226 (e.g., in the longitudinal direction 1204) of the shaft 1212. For example, the first primary bearing 1244 may be configured to block or limit movement (e.g., translation, axial movement) of the shaft 1212 along the rotational axis 1226 and/or relative to the longitudinal axis 1204. The compressor 1105 (e.g., the bearing system 1140) may also include a second primary bearing 1246 (e.g., first radial bearing, first magnetic radial bearing) and a third primary bearing 1248 (e.g., second radial bearing, second magnetic radial bearing). The second primary bearing 1246 and the third primary bearing 1248 may block movement (e.g., bending, radial movement, eccentric rotation) of the shaft 1212 in a direction crosswise to the rotational axis 1226, such as in the radial direction 1206.

In the illustrated embodiment, the third primary bearing 1248 and the impeller 1214 are positioned at or coupled to a first end 1232 (e.g., a first axial end, a first longitudinal end) of the shaft 1212, and the second primary bearing 1246 is positioned at or coupled to a second end 1233 (e.g., a second axial end, a second longitudinal end), opposite the first end 1232, of the shaft 1212. Additionally, the first primary bearing 1244 is disposed at the first end 1232 of the shaft 1212, and the third primary bearing 1248 is disposed between the impeller 1214 and the first primary bearing 1244 relative to the rotational axis 1226 (e.g., the longitudinal axis 1204). Thus, the first primary bearing 1244 and the third primary bearing 1248 are disposed opposite the second primary bearing 1246 relative to the motor 1218 (e.g., the rotor 1230, the stator 1228). However, it should be appreciated that the primary bearings 1242 of the bearing system 1140 may be arranged along the shaft 1212 in other configurations in some embodiments. For example, the first primary bearing 1244 (e.g., thrust bearing) may be disposed at the second end 1233 of the shaft 1212 adjacent the second primary bearing 1246. Furthermore, it should be appreciated that while three primary bearings 1242 (e.g., a first primary bearing 1244, a second primary bearing 1246, a third primary bearing 1248) are illustrated, any number (e.g., one, two, four, or more) of primary bearings 1242 may be employed by the bearing system 1140.

In any case, the primary bearings 1242 of the bearing system 1140 are configured to enable desired positioning and rotation of the shaft 1212 and the impeller 1214 during operation of the compressor 1105. Specifically, the primary bearings 1242 are configured to support a load (e.g., axial load, radial load) on the shaft 1212 via imparting magnetic forces onto the shaft 1212 to cause the shaft 1212 to levitate within (e.g., radially within, axially within) the primary bearings 1242. To this end, the compressor 1105 (e.g., the computer cooling system 1100) may include a bearing controller 1250 (e.g., magnetic bearing controller) communicatively coupled to the primary bearings 1242 and configured to regulate operation of the primary bearings 1242. The bearing controller 1250 may, for example, be configured to regulate a respective flow of current supplied to each primary bearing 1242 to maintain levitation and/or a position of the shaft 1212 (e.g., relative to the longitudinal axis 1204 and/or the radial axis 1206). Similarly, the bearing controller 1250 may adjust or alter the respective flow of current supplied to one or more of the primary bearings 1242 to adjust levitation and/or a position (e.g., axial position, radial position) of the shaft 1212. For example, the bearing controller 1250 may adjust an electrical current provided to the second primary bearing 1246 and/or the third primary bearing 1248 to adjust a magnetic force (e.g., electromagnetic force, magnetic field, radial magnetic force) imparted radially (e.g., radially inward, toward the rotational axis 1226) onto the shaft 1212.

The bearing controller 1250 may also adjust an electrical current provided to the first primary bearing 1244 to adjust a magnetic force (e.g., electromagnetic force, magnetic field, axial magnetic force) imparted onto a collar 1234 (e.g., thrust collar, thrust disk) fixedly attached to the shaft 1212. For example, the first primary bearing 1244 may include multiple magnetic bearing components 1235 (e.g., windings, electromagnets) that are each configured to receive a respective flow of electrical current from the bearing controller 1250 and to generate a force along the longitudinal axis 1204. Specifically, the collar 1234 may extend radially outward from the shaft 1212 and may be disposed between the magnetic bearing components 1235 (e.g., relative to the longitudinal axis 204) of the first primary bearing 1244. In this way, a first magnetic bearing component 1237 of the first primary bearing 1244 may apply a first magnetic force 1245 to the collar 1234, and therefore the shaft 1212, in a first direction 1236, and a second magnetic bearing component 1239 of the first primary bearing 1244 may apply a second magnetic force 1247 to the collar 1234 and the shaft 1212 in a second direction 1238, opposite the first direction 1236.

In certain embodiments, the bearing controller 1250 (e.g., automation controller, electronic controller) may be a component of a control system 1150 (e.g., control panel 344, controller, main controller, automation controller, electronic controller, chiller controller) of the cooling system 1100. The control system 1150 may be configured to control and/or regulate operation of the computer cooling system 1100 and components thereof, and may include processing circuitry 1152, which may execute software for controlling the cooling system 1100 (e.g., bearing system 1140, bearing controller 1250) and/or components thereof. The control system 1150 may also include a memory 1154 that may store information, such as instructions for the processing circuitry 1152 to execute.

As noted above, the bearing system 1140 may also include one or more backup bearings 1243 configured to support and enable rotation of the shaft 1212, such as during instances in which operation of the primary bearings 1242 (e.g., first primary bearing 1244, second primary bearing 1246, third primary bearing 1248) is inadvertently (e.g., unexpectedly) interrupted and/or otherwise adversely impacted. In certain embodiments, each backup bearing 1243 may be associated with and/or positioned adjacent to a respective primary bearing 1242 (e.g., first primary bearing 1244, second primary bearing 1246, third primary bearing 1248). For example, each of the backup bearings 1243 may be housed with the first primary bearing 1244, the second primary bearing 1246, or the third primary bearing 1248 (e.g., within a bearing housing corresponding to the first primary bearing 1244, the second primary bearing 1246, or the third primary bearing 1248). That is, in certain embodiments, a first bearing assembly of the bearing system 1140 may include a bearing housing that encases the first primary bearing 1244 and one of the backup bearings 1243. Likewise, a second bearing assembly of the bearing system 1140 may include another bearing housing that encases the second primary bearing 1246 and another backup bearing 1243. In certain embodiments, the second bearing assembly may also include the third primary bearing 1248 supported by the corresponding bearing housing. In other embodiments, the backup bearings 1243 may be positioned a threshold distance away from the primary bearings 1242 and may each be housed within separate respective bearing housings (e.g., backup bearing housings).

Each of the backup bearings 1243 may be configured to reduce, limit, or mitigate an amount of metal-to-metal contact within the compressor 1105, thereby limiting an amount of particulates, contaminants, or impurities that may otherwise be generated based on metal-to-metal contact within the compressor 1105. To this end, at least a portion (e.g., a shaft contacting surface) of each of the backup bearings 1243 that is configured to contact the shaft 1212 (e.g., when operation of the primary bearings 1242 is inadvertently interrupted) may include or be formed from a non-conductive material, such as ceramic, silicon nitride, or zirconium dioxide. For example, one or more of the backup bearings 1243 may be a mechanical bearing, such as a ball bearing, a journal bearing, a sleeve bearing, a bushing, or a roller bearing. In embodiments of the backup bearings 1243 configured as ball bearings (e.g., angular contact ball bearings, deep groove ball bearings), one or more of the ball bearings may include an inner raceway, an outer raceway, and one or more ball bearings disposed between the inner raceway and the outer raceway to facilitate movement (e.g., rotation) of the raceways relative to one another. An interior surface (e.g., radially-inward surface, contact surface, bearing surface, inner diameter, inner circumference) of the inner raceway, which may be configured to contact the shaft 1212 of the compressor 1105 during certain operating conditions (e.g., during instances in which the primary bearings 1242 of the bearing system 1140 are inoperative), may be formed from or may be lined with the non-conductive material, thereby limiting metal-to-metal contact within the compressor 1105 (e.g., between the interior surface of the inner raceway and the outer surface 1213 of the shaft 1212 of the compressor 1105).

It should be appreciated that the present techniques may also be incorporated with embodiments of the compressor having other types of primary bearings 1242. For example, in certain embodiments, the primary bearings 1242 may be configured to receive a pressurized fluid, such as the working fluid 1104 circulated by the cooling system 1100 and discharge the pressurized fluid toward the shaft 1212 to enable levitation and positional adjustment of the shaft 1212 within the compressor 1105.

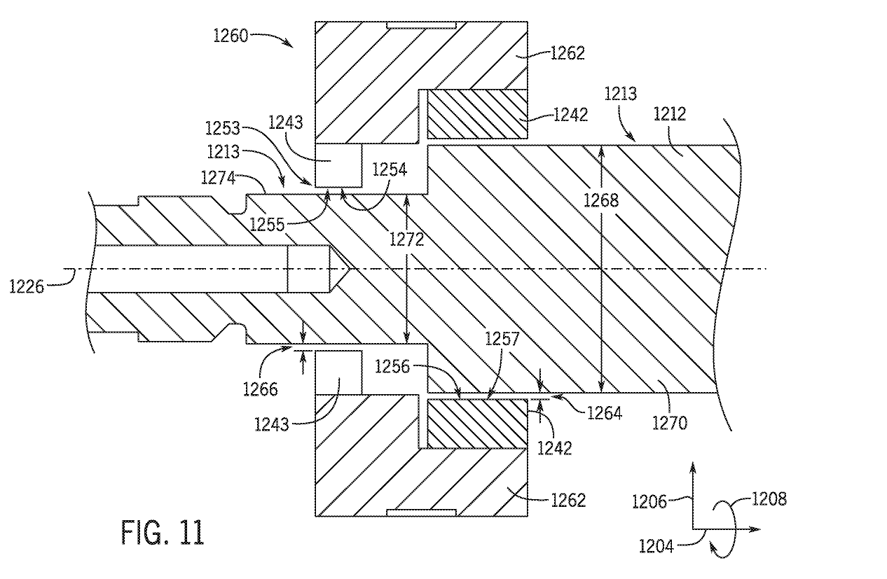

FIG. 11 is a detailed cross-sectional side view of an embodiment of a portion of the compressor 1105 including a bearing assembly 1260 (e.g., bearing arrangement, bearing system) of the bearing system 1140, in accordance with aspects of the present disclosure. For example, the bearing assembly 1260 may include an embodiment of the primary bearing 1242 (e.g., first primary bearing 1244, second primary bearing 1246, third primary bearing 1248) and an embodiment of the backup bearing 1243. In some embodiments, the bearing assembly 1260 is an axial bearing assembly (e.g., thrust bearing assembly) of the bearing system 1140 having an embodiment of the primary bearing 1242 (e.g., first primary bearing 1244) and an embodiment of the backup bearing 1243 configured to support the shaft 1212 within the housing 1210 of the compressor 1105 to enable positional adjustment of the shaft 1212 along the rotational axis 1226 while limiting metal-to-metal contact within the compressor 1105. In other embodiments, the bearing assembly 1260 is a radial bearing assembly of the bearing system 1140 having an embodiment of the primary bearing 1242 (e.g., second primary bearing 1246 and/or third primary bearing 1248) and an embodiment of the backup bearing 1243 configured to support the shaft 1212 within the housing 1210 of the compressor 1105 to enable rotation and/or radial positioning (e.g., relative to the rotational axis 1226) of the shaft 1212 while limiting metal-to-metal contact within the compressor 1105. In the illustrated embodiment, the bearing assembly 1260 includes a bearing housing 1262. One of the primary bearings 1242 (e.g., magnetic bearing, first primary bearing 1244, second primary bearing 1246, third primary bearing 1248) and/or one of the backup bearings 1243 may be supported (e.g., retained) within the bearing housing 1262. As such, the primary bearing 1242 is disposed about (e.g., around, annularly disposed about) the shaft 1212. As noted above, the primary bearing 1242 is configured to receive a current from the bearing controller 1250, thereby enabling the primary bearing 1242 to impart magnetic forces onto the shaft 1212 of the compressor 1105 to enable desired positioning and/or support (e.g., levitation) of the shaft 1212 during operation of the compressor 1105.

In certain embodiments, the backup bearing 1243 may be positioned outboard of the primary bearing 1242 (e.g., relative to a length-wise or longitudinal center 1211 of the shaft 1212, relative to the stator 1228 of the motor 1218). As discussed above, in certain embodiments, the backup bearing 1243 is supported by (e.g., coupled to, mounted to) the bearing housing 1262, and the backup bearing 1243 is disposed about (e.g., around, annularly disposed about) the shaft 1212. Thus, during interrupted operation of the primary bearing 1242, the backup bearing 1243 may engage with and support the shaft 1212 (e.g., engage with the outer surface 1213 of the shaft 1212) and may enable continued rotation of the shaft 1212 within the bearing assembly 1260 and/or may enable controlled slowdown of rotation of the shaft 1212. For example, a supply of the current from the bearing controller 1250 to the primary bearing 1242 may be inadvertently interrupted, thereby causing the primary bearing 1242 to no longer operate to lift or levitate the shaft 1212. In such instances, the shaft 1212, no longer levitated by the primary bearing 1242, may contact an inner surface 1254 (e.g., contacting surface) of the backup bearing 1243. Thus, the backup bearing 1243 may be configured to at least partially support a load of the shaft 1212. Additionally, the backup bearing 1243 may provide a bearing interface 1253 between the backup bearing 1243 and the outer surface 1213 of the shaft 1212 to enable reduced friction therebetween. In this way, the backup bearing 1243 may enable continued rotation of the shaft 1212. For example, the backup bearing 1243 may enable a controlled and/or regulated deceleration of the shaft 1212, such as during shutdown of the compressor 1105.

Further, the backup bearing 1243 may mitigate wear and degradation to the compressor 1105 and components of the compressor 1105 while limiting (e.g., avoiding) an amount of metal-to-metal contact within the compressor 1105 (e.g., based on the material composition of the backup bearing 1243, based on the material composition of the inner surface 1254 of the backup bearing 1243). For example, as discussed in greater detail below, the inner surface 1254 of the backup bearing 1243 configured to contact the outer surface 1213 of the shaft 1212 may be formed from and/or may be lined with a material 1255 (e.g., non-conductive material, non-metallic), such as ceramic, silicon nitride, zirconium dioxide, and the like. By utilizing a non-conductive material 1255 to form at least a portion of the backup bearings 1243 that directly contacts the shaft 1212 of the compressor 1105, metal-to-metal contact within the compressor 1105 may be reduced, thereby reducing potential creation of particulates, contaminants, or impurities within the compressor 1105 that may otherwise be created via metal-to-metal contact.

It should be appreciated that, under certain operating conditions (e.g., during shutdown of the compressor 1105, when operation of the primary bearing 1242 is inadvertently interrupted), the shaft 1212 may also contact an inner surface 1256 of the primary bearing 1242. However, without current directed through the primary bearing 1242, the inner surface 1256 of the primary bearing 1242 may not adequately support and/or enable rotation of the shaft 1212. As such, in certain embodiments, the backup bearing 1243 may be configured to contact the shaft 1212 before the inner surface 1256 of the primary bearing 1242 that is non-operational. In certain embodiments, the inner surface 1256 of the primary bearing 1242 may also include a non-conductive material 1257, thereby avoiding or reducing metal-to-metal contact within the compressor 1105. In certain embodiments, the non-conductive material 1257 utilized to form portions of the primary bearing 1242 may be different than the non-conductive material 1255 utilized to form portions of the backup bearing 1243, whereas in other embodiments, the non-conductive material 1257, 1255 utilized to form respective portions of the primary bearing 1242 and the backup bearing 1243 is the same.

In certain embodiments, during operation of the primary bearing 1242, the backup bearing 1243 may not engage with (e.g., contact) the shaft 1212. For example, the backup bearing 1243 may be configured to establish a clearance (e.g., radial clearance) between the shaft 1212 and the backup bearing 1243. The clearance between the shaft 1212 and the backup bearing 1243 may be less than a clearance (e.g., radial clearance) established between the primary bearing 1242 and the shaft 1212 during operation of the primary bearing 1242. For example, the primary bearing 1242 may cause the shaft 1212 to levitate a first distance 1264 extending (e.g., radially) from the inner surface 1256 of the primary bearing 1242 during operation of the primary bearing 1242. Additionally, during operation of the primary bearing 1242, the backup bearing 1243 may be positioned to maintain a clearance having a second distance 1266 extending (e.g., radially) between the inner surface 1254 of the backup bearing 1243 (e.g., inner surface 1254 of an inner raceway of the backup bearing 1243) and the shaft 1212. In other words, the backup bearing 1243 may be concentric with the shaft 1212, and an inner radius of the backup bearing 1243 may be greater than a radius of the shaft 1212 by the second distance 1266 at an axial location of the backup bearing 1243 along the shaft 1212. In certain embodiments, the first distance 1264 may be greater than the second distance 1266 by any suitable amount, such as approximately 3 millimeters (mm), 2 mm, 1 mm, 0.5 mm, 0.25 mm, 0.1 mm, 0.01 mm, or any other suitable distance. Thus, in certain embodiments, the inner surface 1254 of the backup bearing 1243 (e.g., the interior surface of an inner raceway of the backup bearing 1243) may contact the shaft 1212 prior to the inner surface 1256 of the primary bearing 1242 contacting the shaft 1212 (e.g., during instances in which the primary bearing 1242 does not operate). In this way, the backup bearing 1243 may mitigate metal-to-metal contact within the compressor 1105. In other embodiments, the first distance 1264 may be less than the second distance 1266.

In the illustrated embodiment, a diameter of the shaft 1212 varies along a length of the shaft 1212 (e.g., along the axis 1226). For example, a first diameter 1268 of the shaft 1212 along a first portion 1270 of the shaft 1212 is greater than a second diameter 1272 along a second portion 1274 of the shaft 1212. In certain embodiments, the primary bearing 1242 may be disposed (e.g., annularly) about the first portion 1270, and the backup bearing 1243 may be disposed (e.g., annularly) about the second portion 1274. However, it should be appreciated that, in certain embodiments, a diameter of the shaft 1212 may remain constant along the length of the shaft 1212. Further, as noted above, while the backup bearing 1243 is described above as being housed in the bearing housing 1262 with a primary bearing 1242, in other embodiments, the backup bearing 1243 may be housed or retained within a separate respective bearing housing (e.g., backup bearing housing).

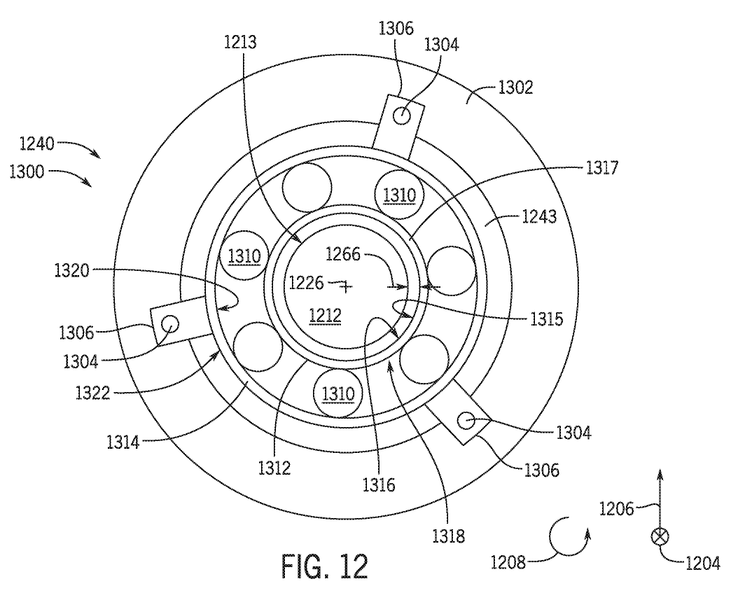

Turning now to FIG. 12, an axial view of an embodiment of a bearing assembly 1300 (e.g., bearing assembly 1260) having an embodiment of the backup bearing 1243 of the bearing system 1140 is shown. The bearing assembly 1300 includes a bearing housing 1302 (e.g., backup bearing housing, bearing housing 1262) configured to retain components of the backup bearing 1243 therein. For example, the backup bearing 1243 may be disposed radially within the bearing housing 1302 (e.g., relative to the axis 1226 of the shaft 1212). In some embodiments, the backup bearing 1243 may be retained within the bearing housing 1302 via fasteners 1304 (e.g., mechanical fasteners, screws, bolts, etc.). The fasteners 1304 may extend through one or more rigid plates 1306 (e.g., retainers, extensions) and into the bearing housing 1302. The rigid plates 1306 may extend radially relative to the axis 1226 and may overlap with (e.g., radially overlap with) the backup bearing 1243 and the bearing housing 1302. Thus, the rigid plates 1306 may retain the backup bearing 1243 within the bearing housing 1302 and may block movement of the backup bearing 1243 relative to the bearing housing 1302 and along the axis 1226. It should be appreciated that in certain embodiments, the bearing assembly 1300 may also include a primary bearing 1242.

In certain embodiments, the backup bearing 1243 may be a mechanical bearing. For example, the backup bearing 1243 may be a ball bearing (e.g., angular contact ball bearings, deep groove ball bearings) or roller bearing having balls or rollers 1310 (e.g., bearing elements) configured to roll (e.g., translate, rotate, slide) along walls (e.g., surfaces, raceways) of the backup bearing 1243. For example, the backup bearing 1243 may include a first raceway 1312 (e.g., inner raceway, inner race, inner wall) and a second raceway 1314 (e.g., outer raceway, outer race, outer wall). The inner raceway 1312 may have a first surface 1316 (e.g., inner surface 1256, radially inward surface relative to the shaft 1212, engaging surface, contacting surface, exterior surface relative to the balls 1310) and a second surface 1318 (e.g., radially outward surface relative to the shaft 1212, interior surface relative to the balls 1310). The outer raceway 1314 may have a first surface 1320 (e.g., radially inward surface relative to the shaft 1212, interior surface relative to the balls 1310) and a second surface 1322 (e.g., radially outward surface relative to the shaft 1212). The balls 1310 may be configured to roll along the second surface 1318 of the inner raceway 1312 and the first surface 1320 of the outer raceway 1314, thereby reducing friction between the shaft 1212 and the backup bearing 1243 (e.g., when operation of the primary bearing 1242 is inadvertently interrupted, during compressor shutdown).

As discussed in detail above, it may be desirable to reduce (e.g., avoid) an amount of metal-to-metal contact within the compressor 1105. To this end, the backup bearing 1243 and/or components thereof (e.g., the inner raceway 1312, the balls 1310, the outer raceway 1314) may be formed from a non-conductive material, such as ceramic, silicon nitride, zirconium dioxide, or any other suitable non-conductive material. More particularly, at least the inner raceway 1312 of the backup bearing 1243 and/or the first surface 1316 thereof may be formed from and/or lined with a non-conductive material 1315 (e.g., non-conductive material 1255, ceramic, silicon nitride, zirconium dioxide, or any other suitable non-conductive material). For example, because the first surface 1316 of the inner raceway 1312 is configured to contact (e.g., engage with) the outer surface 1213 of the shaft 1212 (e.g., when the primary bearing 1242 is inoperative, during compressor shutdown), it may be desirable for the inner raceway 1312 to be formed of a non-conductive material 1315 such that the first surface 1316 of the inner raceway 1312 includes the non-conductive material 1315. In certain embodiments, the inner raceway 1312 may include a material defining a body 1317 of the inner raceway 1312, and an inner diameter of the body (e.g., the first surface 1316) may be lined with the non-conductive material 1315. In certain embodiments, the backup bearing 1243 may be a sleeve bearing, a bush bearing, a journal bearing, a sliding contact bearing, a magnetic bearing, a hydrostatic bearing, or any other suitable type of bearing.

In any case, at least the inner surface (e.g., first surface 1316, inner diameter, inner circumference) of the backup bearing 1243 that is configured to contact the outer surface 1213 of the shaft 1212 may be formed from or may include (e.g., may be lined with, may be sealed with) the non-conductive material 1315. Indeed, by employing the non-conductive material 1315 along at least a portion of the backup bearing 1243 that is configured to directly contact the shaft 1212 of the compressor 1105, metal-to-metal contact within the compressor 1105 may be reduced, thereby reducing a potential amount of particulates, contaminants, or impurities within the compressor 1105. In this way, the working fluid directed through the compressor 1105 may remain free or substantially free of particulates, contaminants, or other impurities, such that the working fluid may be suitable for placing in a heat transfer arrangement with electronic equipment to cool the electronic equipment, as described above.

As set forth above, the present disclosure may provide one or more technical effects useful in operating data center cooling systems that circulate working fluid to cool electronic equipment. For example, embodiments of the present disclosure may include a chiller system that operates to cool a working fluid and circulate the working fluid between the chiller system and the electronic equipment. Said another way, at least a portion of the working fluid circuit may extend through the electronic equipment, such that certain embodiments discussed herein do not include and/or incorporate a CDU heat exchanger and/or an evaporator configured to enable heat transfer between two flows of fluid. Therefore, one or more stages of heat transfer and/or heat exchange included in some cooling systems is omitted, thereby enabling enhanced efficiency of the chiller system and increased heat rejection of heat generated by the electronic equipment.

Moreover, present embodiments include systems and methods for mitigating (e.g., avoiding) the generation or creation of particulates, contaminants, and/or impurities (e.g., mitigating, reducing, and/or avoiding metal-to-metal contact in a compressor of a cooling system) and/or mitigating the exposure of a fluid (e.g., working fluid or conditioning fluid that may be directed toward electronic equipment to cool the electronic equipment) to particulates, contaminants, or other impurities (e.g., materials susceptible to chemical or electrochemical corrosion). For example, present embodiments may include a compressor configured to pressurize and circulate a working fluid through a working fluid circuit of a cooling system (e.g., chiller system, data center cooling system). The working fluid circuit may also include a portion that extends to and from electronic equipment, thereby enabling the working fluid to be directed to the electronic equipment to cool the electronic equipment. The compressor may include one or more components that form a portion of the working fluid circuit and are configured to enable pressurization of the working fluid while mitigating exposure of the working fluid to potential particulates or contaminants within the compressor. In certain cases, the compressor may be arranged or configured in a manner that reduces an amount of metal-to-metal contact within the compressor during operation of the compressor, thereby reducing an amount of particulates, contaminants, and impurities that may be entrained into the working fluid directed through the compressor. For example, the compressor may include a bearing system having one or more bearing assemblies configured to support and facilitate rotation of a shaft of the compressor relative to a housing of the compressor.

The bearing system may include primary bearings configured to impart magnetic forces onto the shaft and/or other components of the shaft to enable desired positioning and/or support of the shaft (e.g., and components connected thereto, such as an impeller of the compressor) during operation of the compressor. The primary bearings may be configured to reduce friction and wear within the compressor and limit an amount of metal-to-metal, thereby improving operational efficiency and extending a service life of the compressor. The bearing system may also include backup bearings configured to support the shaft and enable rotation of the shaft, such as during periods in which operation (e.g., normal operation) of the primary bearings is inadvertently interrupted or suspended. The backup bearings may temporarily enable continued operation and/or controlled (e.g., regulated) slowdown of the compressor during operational interruption of the primary bearings.

At least a portion of the backup bearings, such as an inner raceway and/or inner surface of an inner raceway, configured to contact an outer surface of the shaft may be formed from a non-conductive material, thereby reducing and/or blocking metal-to-metal contact within the compressor (e.g., during operational interruption of the primary bearings). The reduction in metal-to-metal contact achieved by the backup bearings may mitigate the generation of particulates, contaminants, and/or other impurities that may otherwise be entrained within the working fluid circulated by the compressor. By maintaining the working fluid free or substantially free of such particulates and contaminants, the present techniques enable the working fluid to be directed to the electronic equipment for cooling while reducing the risk of degradation or operational disruption to the electronic equipment.

While only certain features and embodiments have been illustrated and described, many modifications and changes may occur to those skilled in the art, such as variations in sizes, dimensions, structures, shapes and proportions of the various elements, values of parameters, such as temperatures and pressures, mounting arrangements, use of materials, colors, orientations, and so forth, without materially departing from the novel teachings and advantages of the subject matter recited in the claims. The order or sequence of any process or method steps may be varied or re-sequenced according to alternative embodiments. It is, therefore, to be understood that the appended claims are intended to cover all such modifications and changes as fall within the true spirit of the disclosure.

Furthermore, in an effort to provide a concise description of the exemplary embodiments, all features of an actual implementation may not have been described, such as those unrelated to the presently contemplated best mode, or those unrelated to enablement. It should be appreciated that in the development of any such actual implementation, as in any engineering or design project, numerous implementation specific decisions may be made. Such a development effort might be complex and time consuming, but would nevertheless be a routine undertaking of design, fabrication, and manufacture for those of ordinary skill having the benefit of this disclosure, without undue experimentation.

The techniques presented and claimed herein are referenced and applied to material objects and concrete examples of a practical nature that demonstrably improve the present technical field and, as such, are not abstract, intangible or purely theoretical. Further, if any claims appended to the end of this specification contain one or more elements designated as “means for [perform]ing [a function]…” or “step for [perform]ing [a function]…”, it is intended that such elements are to be interpreted under 35 U.S.C. 112(f). However, for any claims containing elements designated in any other manner, it is intended that such elements are not to be interpreted under 35 U.S.C. 112(f).

1. A compressor for a data center cooling system, comprising:
a compressor housing;
a shaft configured to rotate within the compressor housing; and
a bearing system, comprising:
one or more primary bearings annularly disposed about the shaft, wherein the one or more primary bearings are configured to control a position of the shaft; and
one or more backup bearings annularly disposed about the shaft, wherein each backup bearing of the one or more backup bearings comprises a contacting surface configured to engage with the shaft during an operational interruption to the one or more primary bearings, and wherein the contacting surface is formed from a non-conductive material.

2. The compressor of claim 1, wherein each primary bearing of the one or more primary bearings is a magnetic bearing.

3. The compressor of claim 2, wherein each backup bearing of the one or more backup bearings is a mechanical bearing.

4. The compressor of claim 3, wherein the mechanical bearing comprises a ball bearing, a roller bearing, or both.

5. The compressor of claim 1, wherein the one or more backup bearings are configured to support the shaft during the operational interruption to the one or more primary bearings, during non-operation of the compressor, or both.

6. The compressor of claim 1, wherein the one or more primary bearings are configured to establish a first clearance distance between the one or more primary bearings and the shaft during operation of the one or more primary bearings, the one or more backup bearings are disposed around the shaft at a second clearance distance between the one or more backup bearings and the shaft, and the first clearance distance is greater than the second clearance distance.

7. The compressor of claim 1, comprising:
a first bearing assembly, wherein the first bearing assembly comprises a first primary bearing of the one or more primary bearings and a first backup bearing of the one or more backup bearings; and
a second bearing assembly, wherein the second bearing assembly comprises a second primary bearing of the one or more primary bearings and a second backup bearing of the one or more backup bearings,
wherein the first bearing assembly is disposed about a first end of the shaft, and the second bearing assembly is disposed about a second end of the shaft opposite the first end.

8. The compressor of claim 7, wherein the first backup bearing is positioned outboard of the first primary bearing relative to a longitudinal center of the shaft.

9. The compressor of claim 1, wherein the compressor is configured to circulate a working fluid along a working fluid circuit of the data center cooling system that extends to electronic equipment to cool the electronic equipment via heat transfer from the electronic equipment to the working fluid.

10. The compressor of claim 1, wherein the non-conductive material comprises a ceramic.

11. The compressor of claim 1, wherein the non-conductive material comprises silicon nitride.

12. The compressor of claim 1, wherein the non-conductive material comprises zirconium dioxide.

13. A data center cooling system, comprising:
a working fluid circuit configured to direct a working fluid toward electronic equipment disposed along the working fluid circuit to cool the electronic equipment; and
a compressor, comprising:
a compressor housing;
a shaft configured to rotate within the compressor housing;
a first bearing disposed about the shaft, wherein the first bearing is configured to impart a magnetic force to the shaft to support the shaft; and
a second bearing disposed about the shaft, wherein the second bearing is configured to contact an outer surface of the shaft, and the second bearing comprises a non-conductive material configured to contact the outer surface of the shaft.

14. The data center cooling system of claim 13, wherein the second bearing is configured to contact and support the shaft during an interruption to operation of the first bearing.

15. The data center cooling system of claim 13, wherein the compressor comprises a bearing housing configured to support and retain the first bearing and the second bearing.

16. The data center cooling system of claim 13, wherein at least a portion of the first bearing comprises an additional non-conductive material different than the non-conductive material of the second bearing.

17. A bearing system for supporting a shaft of a compressor, comprising:
a primary bearing disposed about an axis of rotation of the shaft, wherein the primary bearing is configured to establish a first clearance distance between the shaft and the primary bearing during operation of the compressor and the primary bearing; and
a backup bearing disposed about the axis of rotation of the shaft, wherein the backup bearing is configured to encircle the shaft at a second clearance distance between the backup bearing and the shaft during operation of the compressor and the primary bearing, the second clearance distance is less than the first clearance distance, and an inner surface of the backup bearing comprises a non-conductive material configured to contact an outer surface of the shaft during an operational interruption of the primary bearing.

18. The bearing system of claim 17, wherein the primary bearing is a magnetic bearing.

19. The bearing system of claim 17, wherein the magnetic bearing is configured to levitate the shaft in a radial direction, relative to the axis of rotation of the shaft, during operation of the primary bearing, such that the inner surface of the backup bearing does not contact the shaft during operation of the primary bearing.

20. The bearing system of claim 17, wherein the primary bearing is a first primary bearing, the first primary bearing comprises a radial bearing configured to control a radial position of the shaft relative to the axis of rotation, the bearing system comprises a second primary bearing, and the second primary bearing comprises a thrust bearing configured to control an axial position of the shaft along the axis of rotation.
